(19) United States
(12) Patent Application Publication
(10) Pub. No.: US 2025/0274082 A1
(43) Pub. Date: Aug. 28, 2025

(54) POWER AMPLIFIER CIRCUIT

(71) Applicant: Murata Manufacturing Co., Ltd., Nagaokakyo-shi (JP)

(72) Inventor: Masatoshi HASE, Nagaokakyo-shi (JP)

(21) Appl. No.: 19/206,494

(22) Filed: May 13, 2025

Related U.S. Application Data
(63) Continuation of application No. PCT/JP2023/041116, filed on Nov. 15, 2023.

(30) Foreign Application Priority Data
Nov. 16, 2022 (JP) 2022183197

(51) Int. Cl. H03F 1/32; H03F 1/02; H03F 3/21

(52) U.S. Cl. CPC H03F 1/32; H03F 1/0288; H03F 3/211

(57) ABSTRACT

A power amplifier circuit includes a divider circuit, a second-harmonic-wave generating circuit, and a first amplifier circuit. The divider circuit divides an input signal into a first signal and a second signal and outputs the first signal to a main path and the second signal to a sub-path. The first signal and the second signal are out of phase with each other by substantially 180 degrees. The second-harmonic-wave generating circuit is disposed on the sub-path and combines the first signal and the second signal with each other so that a fundamental wave of the first signal and that of the second signal cancel each other out and so that a signal having a frequency band of a second harmonic wave of the first signal and that of a second harmonic wave of the second signal are added to each other, thereby generating a second-harmonic-wave combined signal.

### CROSS REFERENCE TO RELATED APPLICATION

This is a continuation of International Application No. PCT/JP2023/041116 filed on Nov. 15, 2023 which claims priority from Japanese Patent Application No. 2022-183197 filed on Nov. 16, 2022. The contents of these applications are incorporated herein by reference in their entireties.

### BACKGROUND OF THE DISCLOSURE

### Field of the Disclosure

The present disclosure relates to a power amplifier circuit.

### Description of the Related Art

A power amplifier for amplifying power of a transmission signal is loaded in a mobile communication device, such as a mobile phone. When multiple signals whose frequencies are close to each other, for example, are supplied to such a power amplifier, intermodulation distortion (IMD) occurs from multiple signals, which may disturb the linearity of gain. To reduce the influence of such intermodulation distortion, a technology for intentionally inputting a harmonic wave into a signal path to cancel out the components of intermodulation distortion has been proposed. In one example, U.S. Patent Application Publication No. 2005/0242877 discloses a distortion compensating power amplifying apparatus that compensates for intermodulation distortion in the following manner. Output of a first-stage amplifier is divided into the fundamental wave and the second harmonic wave. Then, after the phase and the amplitude of the second harmonic wave are adjusted, the second harmonic wave is added to the fundamental wave and the added wave is inputted into a second-stage amplifier. In another example, U.S. Pat. No. 11,309,849 discloses a distortion compensation circuit including the following filter circuit. The filter circuit attenuates the fundamental wave from output of a first-stage amplifier and allows the second harmonic wave to pass through the filter circuit, thereby compensating for intermodulation distortion.

### BRIEF SUMMARY OF THE DISCLOSURE

Lately, with the introduction of new communication standards, such as 4G (fourth generation mobile communication system) and 5G (fifth generation mobile communication system), the number of frequency bands to be handled by a power amplifier circuit is increasing and the number of filter circuits is accordingly increasing. Additionally, the device disclosed in U.S. Patent Application Publication No. 2005/0242877 and that in U.S. Pat. No. 11,309,849 each include a filter circuit for extracting the second harmonic wave. This enlarges the power amplifier circuit and increases the transmission loss, thereby making it difficult to implement high output.

The present disclosure has been made in view of the above-described background. It is an object of the present disclosure to provide a power amplifier circuit that is able to implement high output as well as to reduce the influence of intermodulation distortion.

To achieve the above-described object, a power amplifier circuit according to an aspect of the disclosure includes a divider circuit, a second-harmonic-wave generating circuit, and a first amplifier circuit. The divider circuit divides an input signal into a first signal and a second signal and outputs the first signal to a main path and the second signal to a sub-path. The first signal and the second signal are out of phase with each other by substantially 180 degrees. The second-harmonic-wave generating circuit is disposed on the sub-path and combines the first signal and the second signal with each other so that a fundamental wave of the first signal and a fundamental wave of the second signal cancel each other out and so that a signal having a frequency band of a second harmonic wave of the first signal and a signal having a frequency band of a second harmonic wave of the second signal are added to each other, thereby generating a second-harmonic-wave combined signal. The first amplifier circuit amplifies a signal, which is obtained by combining a fundamental signal based on the first and second signals received via the main path and an adjusted signal based on the second-harmonic-wave combined signal received via the sub-path with each other, and outputs an amplified signal.

According to the present disclosure, it is possible to provide a power amplifier circuit that is able to implement high output as well as to reduce the influence of intermodulation distortion.

### BRIEF DESCRIPTION OF THE SEVERAL VIEWS OF THE DRAWINGS

FIG. 1 illustrates an example of the configuration of a power amplifier circuit according to a first embodiment.

FIG. 2 illustrates an example of the specific configuration of the power amplifier circuit according to the first embodiment.

FIG. 3 illustrates the specific configuration of a second-harmonic-wave generating circuit and signal waveforms.

FIG. 4 is a vector diagram illustrating a signal whose phase and amplitude are adjusted in a phase adjusting circuit.

FIG. 5 is a spectrum diagram of signals to be supplied to an amplifier circuit of the drive stage.

FIG. 6 is a spectrum diagram illustrating that third-order intermodulation distortion of a signal output from the amplifier circuit of the drive stage is canceled.

FIG. 7 illustrates an example of the configuration of a power amplifier circuit according to a second embodiment.

FIG. 8 illustrates an example of the configuration of a power amplifier circuit according to a third embodiment.

FIG. 9 illustrates an example of the configuration of a power amplifier circuit according to a fourth embodiment.

FIG. 10 illustrates an example of the configuration of a power amplifier circuit according to a fifth embodiment.

FIG. 11 illustrates an example of the configuration of a phase adjusting circuit in the power amplifier circuit of the fifth embodiment.

FIG. 12 illustrates the configuration of a phase adjusting circuit in a first modified example of the power amplifier circuit of the fifth embodiment.

FIG. 13 illustrates the configuration of a phase adjusting circuit in a second modified example of the power amplifier circuit of the fifth embodiment.

FIG. 14 illustrates the configuration of a phase adjusting circuit in a third modified example of the power amplifier circuit of the fifth embodiment.

FIG. 15 illustrates the configuration of a phase adjusting circuit in a fourth modified example of the power amplifier circuit of the fifth embodiment.

### DETAILED DESCRIPTION OF THE DISCLOSURE

Embodiments of the present disclosure will be described below in detail with reference to the drawings. The same element is designated by like reference numeral and an explanation thereof will not be repeated.

[symbol]

Power Amplifier Circuit 100a According to First Embodiment

[symbol]

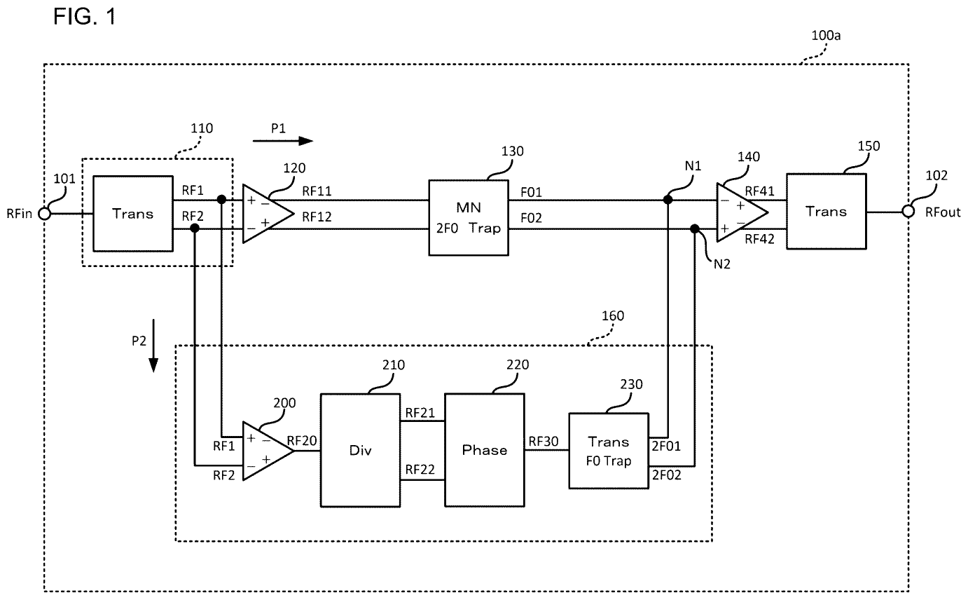

FIG. 1 illustrates an example of the configuration of a power amplifier circuit 100a according to a first embodiment. For example, the power amplifier circuit 100a shown in FIG. 1 is loaded in a mobile communication device, such as a mobile phone, and is used for amplifying power of a radio-frequency (RF) signal to be transmitted to a base station. In one example, the power amplifier circuit 100a amplifies power of a signal of a communication standard, such as 2G (second generation mobile communication system), 3G (third generation mobile communication system), 4G (fourth generation mobile communication system), 5G (fifth generation mobile communication system), LTE (Long Term Evolution)—FDD (Frequency Division Duplex), LTE-TDD (Time Division Duplex), LTE-Advanced, or LTE-Advanced Pro. The frequency of a RF signal is about several hundreds of megahertz to several tens of gigahertz, for example. The communication standard and the frequency of a signal amplified by the power amplifier circuit 100A are not limited to those discussed above.

The power amplifier circuit 100a includes a divider circuit 110, amplifier circuits 120 and 140, a second-harmonic-wave attenuation circuit 130, a combiner circuit 150, a distortion compensation circuit 160, an input terminal 101, and an output terminal 102. The power amplifier circuit 100a includes a main path P1 and a sub-path P2.

The main path P1 is a path, for example, that allows the fundamental wave of an input signal RFin to pass therethrough. The sub-path P2 is a path, for example, that generates a second harmonic wave for compensating for third-order intermodulation distortion and allows the generated second harmonic wave to pass therethrough.

The divider circuit 110 divides the input signal RFin into a signal RF1 (first signal) and a signal RF2 (second signal). The signal RF1 and the signal RF2 are out of phase with each other by substantially 180 degrees. The divider circuit 110 then outputs the signal RF1 to the main path P1 and the signal RF2 to the sub-path P2, for example. “Substantially 180 degrees” includes a range of 135 to 225 degrees, for example.

The divider circuit 110 includes a balun transformer, for example. The divider circuit 110 may have a function of performing impedance matching between the circuit (not shown) at the stage prior to the divider circuit 110 and the amplifier circuit 120 at the stage subsequent to the divider circuit 110.

Each of the amplifier circuit 120 (second amplifier circuit) and the amplifier circuit 140 (first amplifier circuit) is a differential amplifier circuit that amplifies a difference between RF signals input thereinto and outputs the amplified signal. In one example, the power amplifier circuit 100a amplifies power in two stages.

The amplifier circuit 120 (drive stage, for example) amplifies the signals RF1 and RF2 received from the input terminal 101 via the divider circuit 110 and outputs signals RF11 and RF12 to the second-harmonic-wave attenuation circuit 130.

The amplifier circuit 140 (power stage, for example) is a differential amplifier circuit that amplifies a signal obtained by combining at a node N1 a signal F₀₁ (fundamental signal) output from the second-harmonic-wave attenuation circuit 130 and a signal 2F₀₁ output from the distortion compensation circuit 160 and outputs a signal RF41 to the combiner circuit 150 and that also amplifies a signal obtained by combining at a node N2 a signal F₀₂ (fundamental signal) output from the second-harmonic-wave attenuation circuit 130 and a signal 2F₀₂ output from the distortion compensation circuit 160 and outputs a signal RF42 to the combiner circuit 150.

That is, the signal F₀₁ of the fundamental wave passing via the main path P1 and the signal 2F₀₁ of the second harmonic wave passing via the sub-path P2 are combined at the node N1, and the signal F₀₂ of the fundamental wave passing via the main path P1 and the signal 2F₀₂ of the second harmonic wave passing via the sub-path P2 are combined at the node N2, and the combined signals are supplied to the amplifier circuit 140.

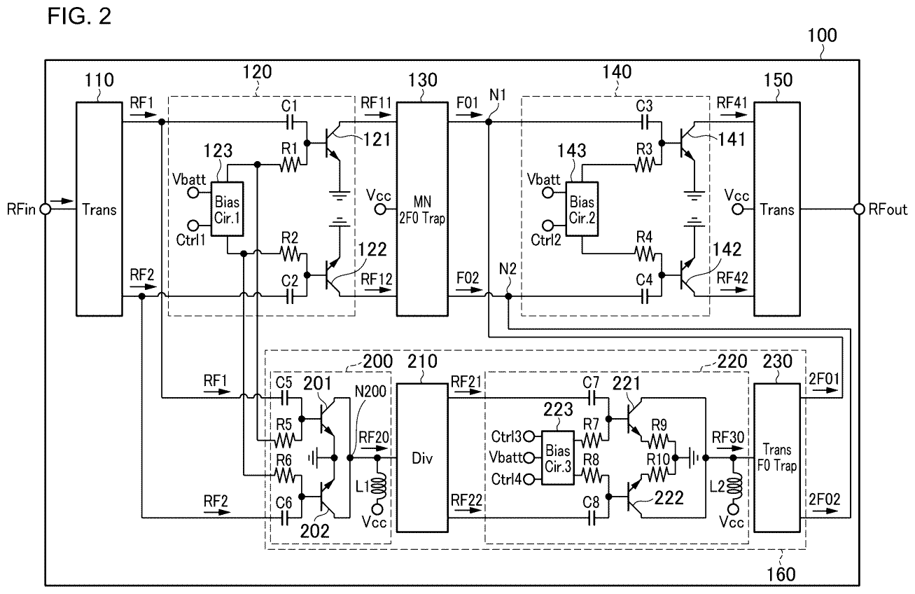

The amplifier circuits 120 and 140 each include a bipolar transistor, such as a heterojunction bipolar transistor (HBT). Instead of the HBT, the amplifier circuits 120 and 140 may each include a field-effect transistor (MOSFET: Metal-oxide-semiconductor Field-Effect Transistor). Hereinafter, an explanation will be given, assuming that each of the amplifier circuits 120 and 140 is constituted by a bipolar transistor, for example. An example of the specific configuration of the amplifier circuits 120 and 140 will be explained below with reference to FIG. 2. FIG. 2 illustrates an example of the specific configuration of the power amplifier circuit 100a according to the first embodiment.

As shown in FIG. 2, the amplifier circuit 120 includes transistors 121 and 122 and a bias circuit 123.

The transistor 121 outputs the signal RF11 generated by amplifying the signal RF1 to the second-harmonic-wave attenuation circuit 130. In the transistor 121, the signal RF1 is inputted into the base via a capacitor C1, the emitter is electrically connected to a reference potential, and the collector is electrically connected to the second-harmonic-wave attenuation circuit 130.

The transistor 122 outputs the signal RF12 generated by amplifying the signal RF2 to the second-harmonic-wave attenuation circuit 130. In the transistor 122, the signal RF2 (signal out of phase with the signal RF1 by 180 degrees) is inputted into the base via a capacitor C2, the emitter is electrically connected to a reference potential, and the collector is electrically connected to the second-harmonic-wave attenuation circuit 130.

The bias circuit 123 supplies a bias to the base of the transistor 121 via a resistor R1 and a bias to the base of the transistor 122 via a resistor R2. The bias circuit 123 controls a bias to be supplied to the transistor 121 and a bias to be supplied to the transistor 122 by using a control signal Ctrl1, for example.

As shown in FIG. 2, the amplifier circuit 140 includes transistors 141 and 142 and a bias circuit 143. The transistors 141 and 142 may be bipolar transistors, such as heterojunction bipolar transistors (HBTs) or field-effect transistors (MOSFETS: Metal-oxide-semiconductor Field-Effect Transistors).

The transistor 141 outputs the signal RF41 obtained by combining the signal F₀₁, which is generated by attenuating the second harmonic wave of the signal RF1, output from the second-harmonic-wave attenuation circuit 130 and the signal 2F₀₁ of the second harmonic wave, which is outputted from the distortion compensation circuit 160, to the combiner circuit 150. In the transistor 141, the second-harmonic-wave attenuation circuit 130 is electrically connected to the base via a capacitor C3, the emitter is electrically connected to a reference potential, and the collector is electrically connected to the distortion compensation circuit 160.

The transistor 142 outputs the signal RF42 obtained by combining the signal F₀₂, which is generated by attenuating the second harmonic wave of the signal RF2, output from the second-harmonic-wave attenuation circuit 130 and the signal 2F₀₂ of the second harmonic wave, which is outputted from the distortion compensation circuit 160, to the combiner circuit 150. In the transistor 142, the second-harmonic-wave attenuation circuit 130 is electrically connected to the base via a capacitor C4, the emitter is electrically connected to a reference potential, and the collector is electrically connected to the distortion compensation circuit 160.

The bias circuit 143 supplies a bias to the base of the transistor 141 via a resistor R3 and a bias to the base of the transistor 142 via a resistor R4. The bias circuit 143 controls a bias to be supplied to the transistor 141 and a bias to be supplied to the transistor 142 by using a control signal Ctrl2, for example.

In the power amplifier circuit 100a, by the use of a differential power amplifier circuit for the power stage, the output impedance is increased, which can lower the impedance of a load, thereby achieving high output. The use of a differential power amplifier circuit can also widen the bandwidth, thereby making it possible to eliminate in-phase signals and thus to reduce the influence of external noise.

The second-harmonic-wave attenuation circuit 130 (output circuit) is disposed on the main path P1 between the divider circuit 110 and the combiner circuit 150, for example, and has a function of attenuating harmonic distortion (HD) occurring by the amplifying operation of the amplifier circuit 120. More specifically, the second-harmonic-wave attenuation circuit 130 may include a low pass filter (LPF) circuit having frequency characteristics that allow the fundamental wave to pass through the LPF and attenuate the second harmonic wave. The second-harmonic-wave attenuation circuit 130 allows the signals F₀₁ and F₀₂ (fundamental signals) with the attenuated second harmonic wave to pass therethrough and to be outputted to the amplifier circuit 140.

With this configuration, the power amplifier circuit 100a can prevent the second harmonic wave contained in the signal passing through the main path P1 from being supplied to the amplifier circuit 140. This can avoid the deterioration of the distortion compensation effect, which may be caused by the second harmonic wave passing through the main path P1 canceling out the signals 2F₀₁ and 2F₀₂ that have not been inputted into the amplifier circuit 140. The deterioration of the distortion compensation effect will be discussed later.

The second-harmonic-wave attenuation circuit 130 may have a function of performing impedance matching between the amplifier circuits 120 and 140.

The combiner circuit 150 is disposed at the stage subsequent to the amplifier circuit 140, and combines the signals RF41 and RF42 output from the amplifier circuit 140 and outputs a signal RFout. The combiner circuit 150 may have a function of performing impedance matching between the amplifier circuit 140 and the circuit (not shown) at the stage subsequent to the output terminal 102.

The combiner circuit 150 may also have a function of short-circuiting the second harmonic wave contained in the signals RF41 and RF42 to a ground. This enables the power amplifier circuit 100a to output the signal RFout with the attenuated second harmonic wave from the output terminal 102.

The distortion compensation circuit 160 is a circuit that is disposed on the sub-path P2 and that cancels the fundamental wave of differential signals obtained by dividing the input signal RFin in the divider circuit 110 and generates a signal of the second harmonic wave for compensating for third-order intermodulation distortion.

This will be discussed more specifically. The distortion compensation circuit 160 combines the signal RF1 (first signal) and the signal RF2 (second signal) with each other so that the fundamental wave of the signal RF1 and that of the signal RF2 cancel each other out and so that a signal having a frequency band of the second harmonic wave of the signal RF1 and a signal having a frequency band of the second harmonic wave of the signal RF2 are added to each other. The distortion compensation circuit 160 then adjusts the phase of the combined signal and outputs the signals 2F₀₁ and 2F₀₂ (adjusted signals).

That is, the distortion compensation circuit 160 intentionally generates the signals 2F₀₁ and 2F₀₂ of the second harmonic wave to compensate for third-order intermodulation distortion.

As illustrated in FIG. 2, the distortion compensation circuit 160 includes a second-harmonic-wave generating circuit 200, a divider 210, a phase adjusting circuit 220, and a divider 230, for example.

The second-harmonic-wave generating circuit 200 is a circuit that generates a signal having a frequency band of the second harmonic wave from the signals RF1 and RF2.

More specifically, the second-harmonic-wave generating circuit 200 combines the signal RF1 (first signal) and the signal RF2 (second signal) so that the fundamental wave of the signal RF1 and that of the signal RF2 cancel each other out and so that the signal having a frequency band of the second harmonic wave of the signal RF1 and that of the signal RF2 are added to each other, thereby generating a signal RF20 (second-harmonic-wave combined signal).

As shown in FIG. 2, the second-harmonic-wave generating circuit 200 includes transistors 201 and 202. In the transistor 201, the signal RF1 obtained by dividing the input signal RFin in the divider circuit 110 is inputted into the base, and the emitter is electrically connected to a reference potential.

In the transistor 202, the signal RF2 obtained by dividing the input signal RFin in the divider circuit 110 is inputted into the base, the emitter is electrically connected to a reference potential, and the collector is electrically connected to the collector of the transistor 201.

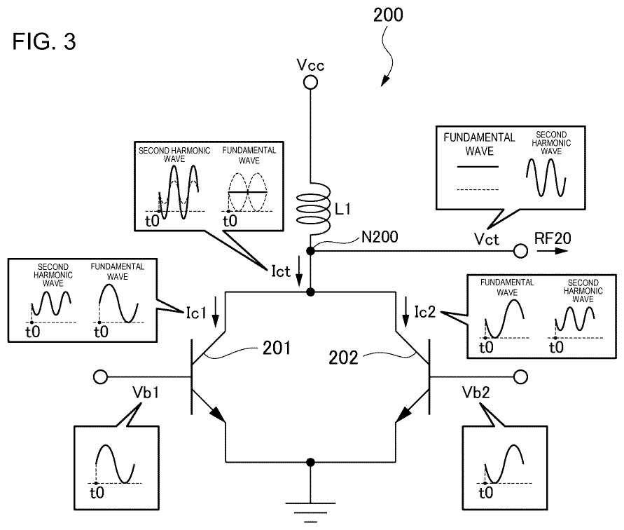

The mechanism for canceling out the fundamental waves and generating a signal of the second harmonic wave in the second-harmonic-wave generating circuit 200 will be explained below with reference to FIG. 3. FIG. 3 illustrates the specific configuration of the second-harmonic-wave generating circuit 200 and signal waveforms. The above-described mechanism will be explained below by using the signal waveforms in the individual portions of the second-harmonic-wave generating circuit 200.

As illustrated in FIG. 3, a voltage Vb1 indicating a first phase of the signal RF1 is inputted into the base of the transistor 201 of the second-harmonic-wave generating circuit 200. A collector current Ic1 corresponding to the voltage Vb1 flows through the collector of the transistor 201. The phase of the fundamental wave of the collector current Ic1 is the same as the first phase of the voltage Vb1. At this time, the second harmonic wave of the collector current Ic1 is generated.

A voltage Vb2 indicating a second phase of the signal RF2 is inputted into the base of the transistor 202 of the second-harmonic-wave generating circuit 200. The second phase is out of phase with the first phase by 180 degrees. A collector current Ic2 corresponding to the voltage Vb2 flows through the collector of the transistor 202. The fundamental wave of the collector current Ic2 is out of phase with the first phase of the voltage Vb1 by 180 degrees. At this time, the second harmonic wave of the collector current Ic2 is generated.

The phase of the second harmonic wave of the collector current Ic1 is the same as that of the collector current Ic2. As expressed by the following equation (1), an even-numbered harmonic wave is raised to an even power, which makes the phase of the harmonic wave positive. Accordingly, the second harmonic waves of the fundamental waves which are out of phase with each other are in phase with each other.

$$y ( t ) = {c}_{0} + {c}_{1} x ( t ) + {{c}_{2} [ x ( t ) ]}^{2} + {{c}_{3} [ x ( t ) ]}^{3} + … \qquad ( 1 )$$

where t is the time and C₀, C₁, C₂, and C₃ are constants.

In the second-harmonic-wave generating circuit 200, the collector current Ic1 and the collector current Ic2 are combined with each other at a node N200 and the signal RF20 is outputted.

When combining the collector currents Ic1 and Ic2, the fundamental wave of the collector current Ic1 and that of the collector current Ic2 cancel each other out. Meanwhile, the second harmonic wave of the collector current Ic1 and that of the collector current Ic2 are in phase and are thus added to each other. That is, the second-harmonic-wave generating circuit 200 outputs, as the signal RF20, a voltage Vct corresponding to a current obtained by adding the second harmonic wave of the collector current Ic1 and that of the collector current Ic2 to each other.

By including the second-harmonic-wave generating circuit 200, the power amplifier circuit 100a is able to attenuate the fundamental wave and to output the second harmonic wave without using a filter circuit, thereby making it possible to reduce the circuit scale.

The divider 210 divides the signal RF20 into a signal RF21 and a signal RF22, which are out of phase with each other by substantially 90 degrees. The divider 210 may be constituted by a hybrid coupler, for example. “Substantially 90 degrees” includes a range of 45 to 135 degrees, for example.

The phase adjusting circuit 220 is disposed at the stage subsequent to the divider 210. The phase adjusting circuit 220 is a circuit that adjusts the phase and the amplitude of the signals RF21 and RF22 (second-harmonic-wave combined signal) and outputs a signal RF30 (adjusted signal).

That is, the phase adjusting circuit 220 adjusts the signals, which are obtained by the divider 210 dividing the signal RF20 of the second harmonic wave generated in the second-harmonic-wave generating circuit 200, so that the phase and the amplitude of the adjusted signals become suitable for distortion compensation.

As shown in FIG. 2, the phase adjusting circuit 220 includes transistors 221 and 222 and a bias circuit 223.

In the transistor 221, the signal RF21 obtained by dividing the signal RF20 in the divider 210 is inputted into the base, and the emitter is electrically connected to a reference potential.

In the transistor 222, the signal RF22 obtained by dividing the signal RF20 in the divider 210 is inputted into the base, the emitter is electrically connected to a reference potential, and the collector is electrically connected to the collector of the transistor 221.

The bias circuit 223 supplies a bias to the base of the transistor 221 and a bias to the base of the transistor 222 so as to adjust the gain of each of the transistors 221 and 222.

The bias circuit 223 controls a bias (gain, which is discussed later) of the transistor 221 by using a control signal Ctr13 and controls a bias (gain, which is discussed later) of the transistor 222 by using a control signal Ctrl4. The control signals Ctrl3 and Ctrl4 are signals corresponding to the frequency of the input signal RFin, the ambient temperature, or the power supply voltage, for example.

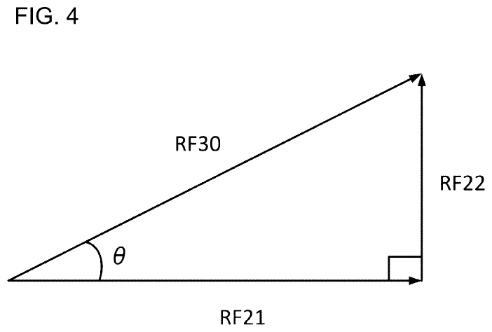

The mechanism for adjusting the phase and the amplitude in the phase adjusting circuit 220 will be explained below with reference to FIG. 4. FIG. 4 is a vector diagram illustrating a signal whose phase and amplitude are adjusted in the phase adjusting circuit 220.

In the phase adjusting circuit 220, the two signals RF21 and Rf22 out of phase with each other are amplified by the corresponding amplifiers (transistors 221 and 222 in this example) having different levels of gain.

As shown in FIG. 4, the phase adjusting circuit 220 outputs the signal RF30, whose phase and amplitude are suitable for distortion compensation, represented by the vector sum of the signals amplified by the individual amplifiers. More specifically, as shown in FIG. 4, the phase adjusting circuit 220 adjusts the gain of the signal RF21 to change the length of its vector and also adjusts the gain of the signal RF22 to change the length of its vector so as to adjust the phase θ and the length (amplitude of the signal) of the vector of the signal RF30 that represents the sum of the vectors of the signals RF21 and RF22.

That is, the phase adjusting circuit 220 is a circuit that is able to adjust the phase and the amplitude of a signal as desired based on two signals, which are out of phase with each other by 90 degrees, and to output the adjusted signal.

With this configuration, even if the operating condition, such as the frequency, temperature, or power supply voltage, is changed, the power amplifier circuit 100a is able to output the signal RF30, whose phase and amplitude are suitable for distortion compensation, in accordance with the changed operating condition.

The divider 230 divides the signal RF30 outputted from the phase adjusting circuit 220 into the signals 2F₀₁ and 2F₀₂, which are out of phase with each other by substantially 180 degrees. The signals 2F₀₁ and 2F₀₂ outputted from the divider 230 on the sub-path P2 are respectively inputted into the nodes N1 and N2 on the main path P1. The divider 230 includes a balun transformer, for example. The divider 230 may have a function of attenuating the fundamental wave and performing impedance matching (impedance conversion) in the frequency range of the second harmonic wave.

With the use of the above-described distortion compensation circuit 160, the power amplifier circuit 100a can generate the signals 2F₀₁ and 2F₀₂ of the second harmonic wave which are intentionally inputted into the amplifier circuit 140.

The provision of the phase adjusting circuit 220 and the divider 230 for the distortion compensation circuit 160 may be omitted. Even in this case, the power amplifier circuit 100a can generate a signal of the second harmonic wave without using a filter circuit and compensate for third-order intermodulation distortion in the main path P1.

In the above-described example, the signals RF1 and RF2 are inputted into the second-harmonic-wave generating circuit 200. However, this is only an example. For instance, in the power amplifier circuit 100a, after the signals RF1 and RF2 are amplified by the amplifier circuit 120, they may be inputted into the second-harmonic-wave generating circuit 200.

The operation for compensating for third-order

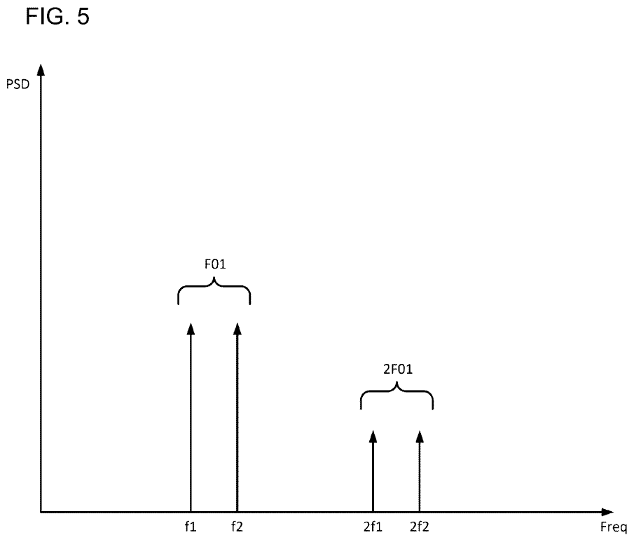

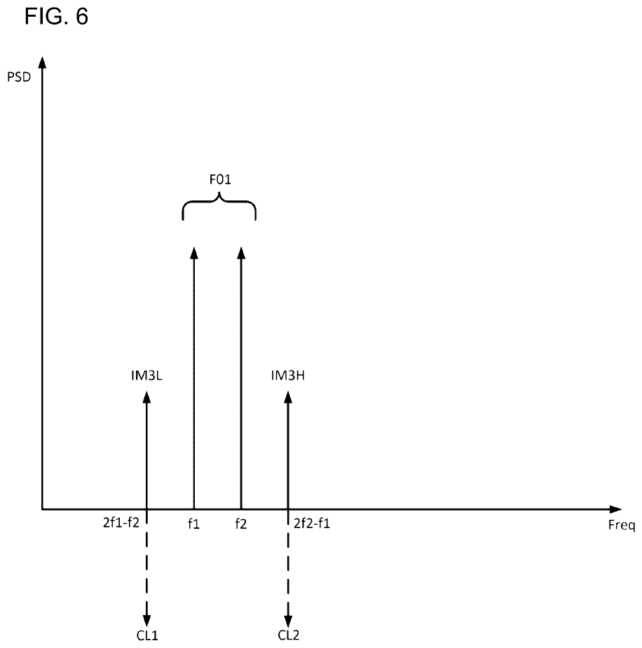

intermodulation distortion will now be discussed below with reference to FIGS. 5 and 6.

FIG. 5 is a spectrum diagram of signals (signals F₀₁ and 2F₀₁ or signals F₀₂ and 2F₀₂ in FIG. 1 in this example) to be supplied to the amplifier circuit 140 of the drive stage. Although the signal components of harmonic waves (second harmonic waves that cause third-order intermodulation distortion) are contained in the signal F₀₁, they are not shown in FIG. 5. The presence of the signal components of the harmonic waves causes the occurrence of third-order intermodulation distortion.

FIG. 6 is a spectrum diagram illustrating that the third-order intermodulation distortion of a signal (signal RF41 or RF42 in FIG. 1 in this example) outputted from the amplifier circuit 140 of the drive stage is canceled.

In one example, among multiple pairs of differential signals to be supplied to the amplifier circuit 140, one pair of differential signals, that is, the signals F₀₁ and 2F₀₁, are shown in FIGS. 5 and 6. In FIGS. 5 and 6, the horizontal axis indicates the frequency of a signal, and the vertical axis indicates power spectral density (PSD).

As illustrated in FIG. 5, the signal F₀₁ of the fundamental wave passing via the main path P1 and the signal 2F₀₁ of the second harmonic wave passing via the sub-path P2 are supplied to the amplifier circuit 140 (transistor 141 in this example). It is assumed that the signal F₀₁ of the fundamental wave includes components of two frequencies f₁ and f₂ (f₁<f₂) close to each other. In this case, the signal 2F₀₁ of the second harmonic wave of each of the frequencies f₁ and f₂ is generated in the sub-path P2. That is, the signal 2F₀₁ of the second harmonic wave includes components of two frequencies 2f₁ and 2f₂. Hence, a combined signal of the signal F₀₁ having the frequencies f₁ and f₂ and the signal 2F₀₁ having the frequencies 2f₁ and 2f₂ is supplied to the amplifier circuit 140.

As a result of the amplifier circuit 140, which exhibits nonlinearity, amplifying the fundamental wave, a third-order intermodulation distortion IM3_{L} having a frequency of 2f₁-f₂ occurs in the lower frequency side of the signal F₀₁ of the fundamental wave (frequency f₁), and a third-order intermodulation distortion IM3_{H} having a frequency of 2f₂-f₁ occurs in the higher frequency side of the signal F₀₁ of the fundamental wave (frequency f₂).

The third-order intermodulation distortions IM3_{L} and IM3_{H} are comparatively close to the frequencies f₁ and f₂ of the signal F₀₁ of the fundamental wave. It is thus difficult to eliminate the third-order intermodulation distortions IM3_{L} and IM3_{H} by the use of a filter circuit or another device. The third-order intermodulation distortions IM3_{L}and IM3_{H} may lower the linearity of the power amplifier circuit 100a. Amplifying of the fundamental wave by the amplifier circuit 140 may cause a third-order intermodulation distortion having a frequency of 2f₁+f₂ and a third-order intermodulation distortion having a frequency of 2f₂+f₁. However, these frequencies are relatively separated from the frequencies f₁ and f₂ of the signal F₀₁ of the fundamental wave, and the third-order intermodulation distortions having these frequencies do not significantly lower the linearity. An explanation of such third-order intermodulation distortions will be thus omitted.

The power amplifier circuit 100a compensates for the third-order intermodulation distortions IM3_{L} and IM3_{H} that are relatively close to the fundamental wave. As described above, the power amplifier circuit 100a intentionally combines the signal 2F₀₁ of the second harmonic wave with the signal F₀₁ of the fundamental wave so as to generate compensation signals CS_{L} and CS_{H} to cancel out the third-order intermodulation distortions IM3_{L} and IM3_{H}.

This will be explained more specifically. In the power amplifier circuit 100a, the signal F₀₁ of the fundamental wave and the signal 2F₀₁ of the second harmonic wave are added to each other at the node N1 and the added signal is amplified in the amplifier circuit 140. Then, the compensation signal CS_{L} having the frequency (2f₁−f₂) representing the difference between the frequency 2f₁, which is one of the two frequencies of the signal 2F₀₁ of the second harmonic wave, and the frequency f₂, which is the other one of the two frequencies of the signal F₀₁ of the fundamental wave, is generated.

In the power amplifier circuit 100a, the compensation signal CS_{H} having the frequency (2f₂−f₁) representing the difference between the frequency 2f₂, which is the other one of the two frequencies of the signal 2F₀₁ of the second harmonic wave, and the frequency f₁, which is one of the two frequencies of the signal F₀₁ of the fundamental wave, is also generated.

In this manner, in the power amplifier circuit 100a, the phase adjusting circuit 220 adjusts the phase of the signal 2F₀₁ of the second harmonic wave so that the phase of the third-order intermodulation distortions IM3_{L} and IM3_{H} occurring in the amplifier circuit 140 and the phase of the compensation signals CS_{L} and CS_{H} become out of phase with each other by substantially 180 degrees in the output of the amplifier circuit 140.

In the power amplifier circuit 100a, the phase adjusting circuit 220 also adjusts the amplitude of the signal 2F₀₁ of the second harmonic wave by the gain adjustments of the transistors 221 and 222 so that the amplitudes of the third-order intermodulation distortions IM3_{L} and IM3_{H} occurring in the amplifier circuit 140 and the amplitudes of the compensation signals CS_{L} and CS_{H} cancel each other out in the output of the amplifier circuit 140.

For the signal F₀₂ of the fundamental wave, as well as for the above-described signal F₀₁ of the fundamental wave, the phase adjusting circuit 220 adjusts the signal 2F₀₂ of the second harmonic wave to cancel the third-order intermodulation distortions, though the adjustment of the signal 2F₀₂ is not discussed above.

As described above, as shown in FIG. 5, the power amplifier circuit 100a cancels out the third-order intermodulation distortions IM3_{L} and IM3_{H} by the compensation signals CS_{L} and CS_{H}. In FIG. 3, the compensation signals CS_{L} and CS_{H} are indicated in the downward direction to show that the compensation signals CS_{L} and CS_{H} are out of phase with the third-order intermodulation distortions IM3_{L} and IM3_{H} by substantially 180 degrees.

Because of the above-described operation, in the power amplifier circuit 100a, it is possible to reduce the influence of the third-order intermodulation distortions IM3_{L} and IM3_{H} occurring in the amplifier circuit 140. This can suppress the degradation of the linearity of the gain in the power amplifier circuit 100a.

In the configuration disclosed in U.S. Patent Application Publication No. 2005/0242877 as a comparative example, a circuit for attenuating the second harmonic wave is not provided in the main path between the divider and the combiner. This inconveniently allows the second harmonic wave generated by the amplifying operation of the first-stage amplifier to pass through the main path. In the configuration disclosed in U.S. Patent Application Publication No. 2005/0242877, although the second harmonic wave is generated in the sub-path, the second harmonic wave passing via the main path and that passing via the sub-path may cancel each other out when being added to each other in the combiner. This may weaken the power of a signal of the second harmonic wave inputted into the amplifier circuit 140.

In contrast, in the power amplifier circuit 100a, the second-harmonic-wave attenuation circuit 130 disposed on the main path P1 has a function of attenuating the second harmonic wave. The power amplifier circuit 100a can thus input the second harmonic wave of high power into the amplifier circuit 140, compared with the configuration of U.S. Patent Application Publication No. 2005/0242877. This enables the power amplifier circuit 100a to reduce the influence of intermodulation distortion as well as to increase the output power, compared with the configuration of U.S. Patent Application Publication No. 2005/0242877.

Additionally, in the configurations of U.S. Patent Application Publication No. 2005/0242877 and U.S. Pat. No. 11,309,849, a filter circuit is disposed on a path into which the second harmonic wave is inputted. In contrast, in the power amplifier circuit 100a, the second-harmonic-wave generating circuit 200 of the distortion compensation circuit 160, which is used for generating the second harmonic wave, is constituted by transistors specially used for generating the second harmonic wave. In the configuration of U.S. Patent Application Publication No. 2005/0242877, the first-stage amplifier serves to amplify the fundamental wave and also to generate the second harmonic wave. Compared with this configuration in U.S. Patent Application Publication No. 2005/0242877, the power amplifier circuit 100a is able to generate the second harmonic wave of high power as well as to reduce the circuit scale. Additionally, the power amplifier circuit 100a does not include a filter circuit for generating the second harmonic wave, as discussed above. The power amplifier circuit 100a is thus able to reduce the circuit scale, as well as to increase the output power, compared with the power amplifier circuit disclosed in U.S. Pat. No. 11,309,849 including a filter circuit for attenuating the fundamental wave and allowing the second harmonic wave to pass therethrough.

Not all the components included in the power amplifier circuit 100a shown in FIG. 1 are required to be provided as individual circuits. Instead, one circuit may have multiple functions.

In the above-described embodiment, the distortion compensation circuit 160 generates the second harmonic wave to compensate for third-order intermodulation distortion by way of example. It is however possible to compensate for even higher-order intermodulation distortion. More typically, when a signal having the frequencies f₁ and f₂ is amplified in the amplifier circuit 140, (2N+1)-th-order (N is an integer of one or greater) intermodulation distortion of the frequencies {(N+1)f₁−Nf₂} and {(N+1)f₂−Nf₁} is generated. In the power amplifier circuit 100a, as a result of the distortion compensation circuit 160 generating a harmonic wave of an integral multiple of the frequency of the fundamental wave, high-order intermodulation distortion can be canceled.

In the above-described embodiment, the divider circuit 110 distributes the signals RF1 and RF2 to the sub-path P2 at the stage prior to the amplifier circuit 120. However, this is only an example. For instance, the signals RF1 and RF2 may be distributed to the sub-path P2 at the stage subsequent to the amplifier circuit 120. In this case, a divider that distributes the signals RF1 and RF2 to the sub-path P2 may be provided at the stage subsequent to the amplifier circuit 120.

[symbol]

Power Amplifier Circuit 100b according to Second Embodiment

[symbol]

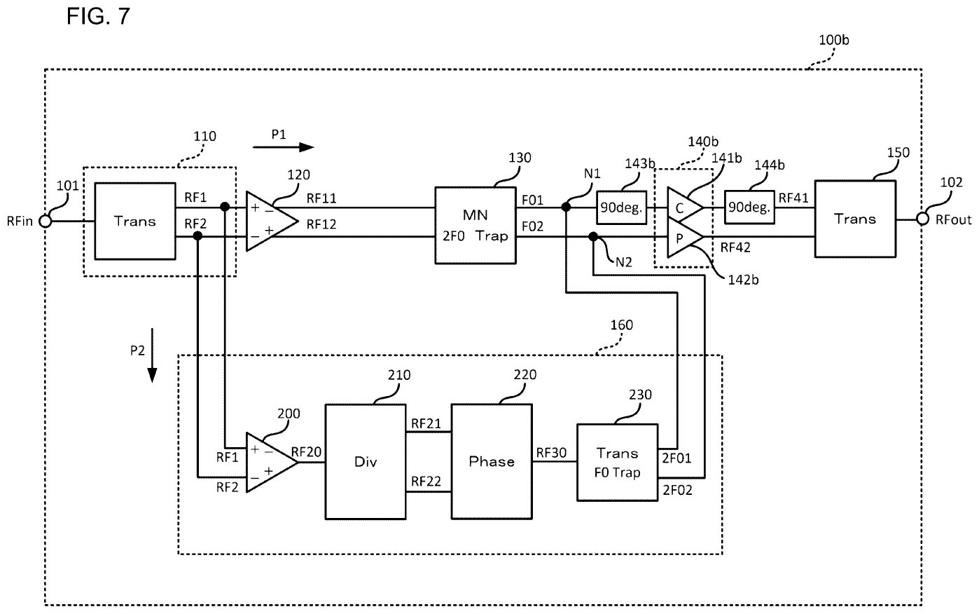

A power amplifier circuit 100b according to a second embodiment will be described below with reference to FIG. 7. FIG. 7 illustrates an example of the configuration of the power amplifier circuit 100b according to the second embodiment. Hereinafter, reference will be given only to the points different from those of the power amplifier circuit 100a of the first embodiment while an explanation of the same points as the power amplifier circuit 100a is being omitted. Similar advantages obtained by the similar configurations of the first embodiment will not be discussed.

The power amplifier circuit 100b is different from the power amplifier circuit 100a illustrated in FIG. 1 in that the amplifier circuit 140, which is constituted by a differential amplifier circuit in the power amplifier circuit 100a, is constituted by a Doherty amplifier circuit. That is, the power amplifier circuit 100b includes a Doherty amplifier circuit 140b.

The Doherty amplifier circuit 140b includes a carrier amplifier 141b, a peak amplifier 142b, a first phase shifter 143b, and a second phase shifter 144b.

For example, a signal obtained by combining at the node N1 the signal F₀₁ outputted from the second-harmonic-wave attenuation circuit 130 and the signal 2F₀₁ outputted from the distortion compensation circuit 160 with each other is inputted into the carrier amplifier 141b via the first phase shifter 143b. The carrier amplifier 141b amplifies this combined signal and outputs the amplified signal. The carrier amplifier 141b is biased to class A, AB, or B, for example. That is, regardless of the power level of the input signal, such as small instantaneous input power, the carrier amplifier 141b amplifies the input signal F₀₁ and outputs the amplified signal.

For example, a signal obtained by combining at the node N2 the signal F₀₂ outputted from the second-harmonic-wave attenuation circuit 130 and the signal 2F₀₂ outputted from the distortion compensation circuit 160 with each other is inputted into the peak amplifier 142b. The peak amplifier 142b amplifies this combined signal and outputs the amplified signal. The peak amplifier 142b is biased to class C, for example. The peak amplifier 142b exercises the amplifying function in a region where the voltage level of the input signal is a predetermined power level or higher, for example. The peak amplifier 142b may be biased to class A, AB, or B, depending on the condition for use.

The first phase shifter 143b is a device that delays the phase by about 90 degrees, and is a ¼-wavelength line, for example. The signal F₀₁ outputted from the second-harmonic-wave attenuation circuit 130 is inputted into one end of the first phase shifter 143b, and the other end of the first phase shifter 143b is electrically connected to the carrier amplifier 141b.

The second phase shifter 144b is a device that delays the phase by about 90 degrees, and is a ¼-wavelength line, for example. The amplified signal outputted from the carrier amplifier 141b is inputted into one end of the second phase shifter 144b, and the other end of the second phase shifter 144b is electrically connected to the combiner circuit 150.

In the power amplifier circuit 100b, the provision of the Doherty amplifier circuit 140b can improve back-off. Additionally, in the power amplifier circuit 100b, by outputting a signal for reducing third-order intermodulation distortion from the distortion compensation circuit 160 to the Doherty amplifier circuit 140b, the linearity of gain can be enhanced.

[symbol]

Power Amplifier Circuit 100c according to Third Embodiment

[symbol]

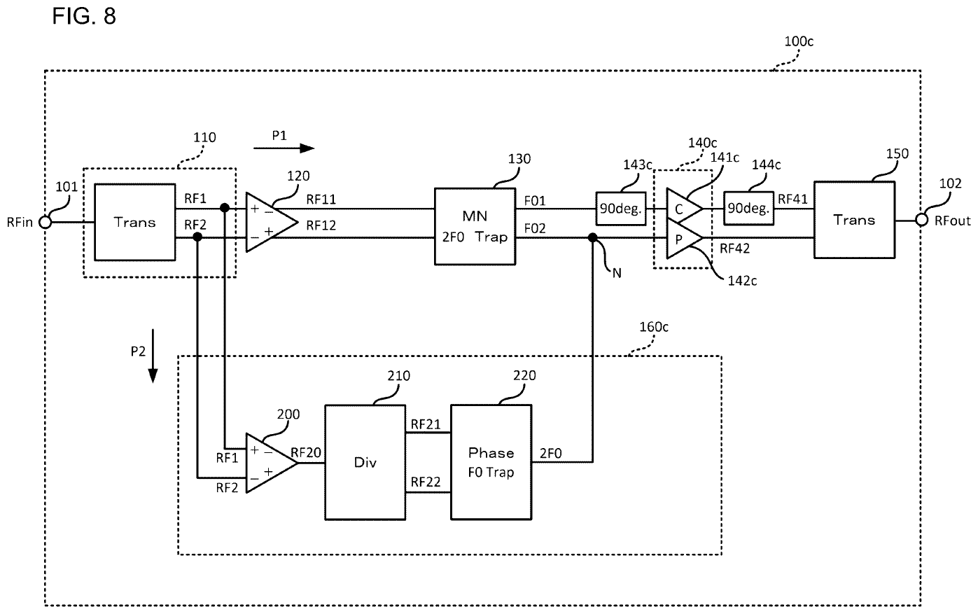

A power amplifier circuit 100c according to a third embodiment will be described below with reference to FIG. 8. FIG. 8 illustrates an example of the configuration of the power amplifier circuit 100c according to the third embodiment. Hereinafter, reference will be given only to the points different from those of the power amplifier circuit 100b of the second embodiment while an explanation of the same points as the power amplifier circuit 100b is being omitted. Similar advantages obtained by the similar configurations of the power amplifier circuit 100a of the first embodiment and the power amplifier circuit 100b of the second embodiment will not be discussed.

The power amplifier circuit 100c is different from the power amplifier circuit 100b in FIG. 2 in that the signal 2F₀ (adjusted signal) of the second harmonic wave used for compensating for third-order intermodulation distortion, which is outputted from a distortion compensation circuit 160c, is inputted only into a peak amplifier 142c.

Unlike the distortion compensation circuit 160 in FIG. 2, the distortion compensation circuit 160c does not include the divider 230. The phase adjusting circuit 220 adjusts the phase and the amplitude of the signals RF21 and RF22 (second-harmonic-wave combined signal) and outputs the signal 2F₀ to the node N. That is, the phase adjusting circuit 220 adjusts the signals obtained by the divider 210 dividing the signal RF20 of the second harmonic wave generated in the second-harmonic-wave generating circuit 200 so that the phase and the amplitude of the signals become suitable for distortion compensation. The phase adjusting circuit 220 may have a function of attenuating the fundamental wave and a function of performing impedance matching (impedance conversion) in the frequency range of the second harmonic wave.

The signal F₀₁ outputted from the second-harmonic-wave attenuation circuit 130, for example, is inputted into a carrier amplifier 141c via a first phase shifter 143c. The carrier amplifier 141c amplifies the signal F₀₁ and outputs the amplified signal.

A signal obtained by combining at the node N the signal F₀₂ outputted from the second-harmonic-wave attenuation circuit 130 and the signal 2F₀ outputted from the distortion compensation circuit 160c with each other, for example, is inputted into the peak amplifier 142c. The peak amplifier 142c amplifies this combined signal and outputs the amplified signal.

In the power amplifier circuit 100c, the provision of a Doherty amplifier circuit 140c can improve back-off. Additionally, in the power amplifier circuit 100c, by outputting the signal 2F₀ used for reducing third-order intermodulation distortion from the distortion compensation circuit 160c to the peak amplifier 142c, whose linearity is poorer, included in the Doherty amplifier circuit 140c, the linearity can be enhanced. The divider 230 provided in the power amplifier circuit 100b can be omitted from the power amplifier circuit 100c, thereby making it possible to reduce the circuit scale.

[symbol]

Power Amplifier Circuit 100d according to Fourth Embodiment

[symbol]

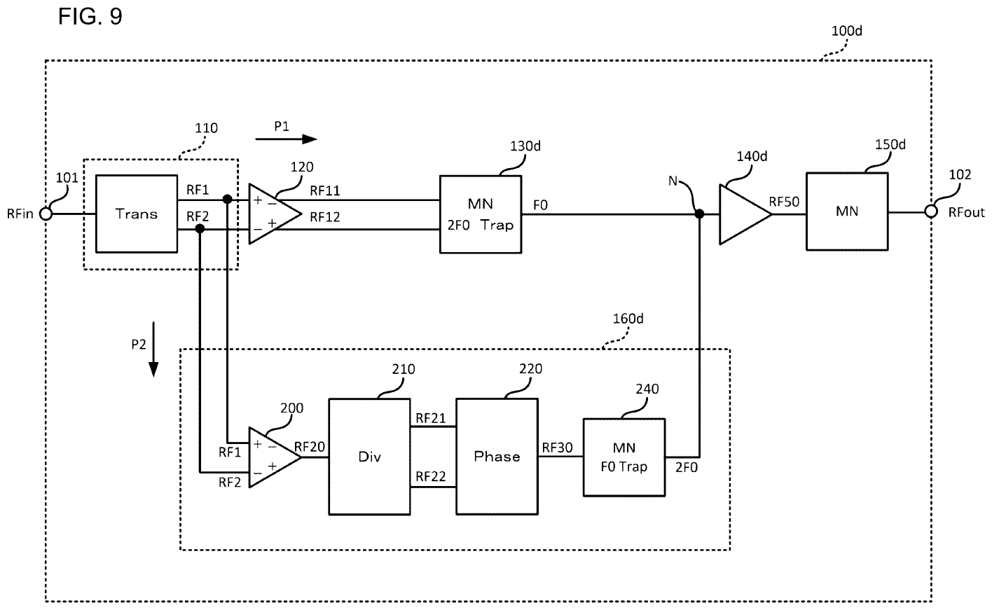

A power amplifier circuit 100d according to a fourth embodiment will be described below with reference to FIG. 9. FIG. 9 illustrates an example of the configuration of the power amplifier circuit 100d according to the fourth embodiment. Hereinafter, reference will be given only to the points different from those of the power amplifier circuit 100a of the first embodiment while an explanation of the same points as the power amplifier circuit 100a is being omitted. Similar advantages obtained by the similar configurations of the power amplifier circuit 100a of the first embodiment will not be discussed.

Unlike the power amplifier circuit 100a in FIG. 1 in which the amplifier circuit 140 is constituted by a differential amplifier circuit, an amplifier circuit 140d of the power amplifier circuit 100d is constituted by a single amplifier circuit.

A second-harmonic-wave attenuation circuit 130d (output circuit) is disposed on the main path P1 between the divider circuit 110 and a matching circuit 150d, for example, and has a function of attenuating harmonic distortion (HD) occurring by the amplifying operation of the amplifier circuit 120. The second-harmonic-wave attenuation circuit 130 receives differential signals (signals RF11 and RF12) and outputs a single signal F₀.

The amplifier circuit 140d is an amplifier circuit that amplifies a signal obtained by combining at the node N the signal F₀ outputted from the second-harmonic-wave attenuation circuit 130d and the signal 2F₀ outputted from a distortion compensation circuit 160d with each other and that outputs the resulting signal RF50 to the combiner circuit 150.

The matching circuit 150d is disposed at the stage subsequent to the amplifier circuit 140 and performs impedance matching between the amplifier circuit 140d and the circuit (not shown) at the stage subsequent to the output terminal 102.

Instead of the divider 230 provided in the distortion compensation circuit 160, the distortion compensation circuit 160d includes a matching circuit 240. The distortion compensation circuit 160d combines the signal RF1 (first signal) and the signal RF2 (second signal) so that the fundamental wave of the signal RF1 and that of the signal RF2 cancel each other out and so that a signal having a frequency band of the second harmonic wave of the signal RF1 and a signal having a frequency band of the second harmonic wave of the signal RF2 are added to each other. The distortion compensation circuit 160d then adjusts the phase of the combined signal and outputs the signal 2F₀ (adjusted signal).

The matching circuit 240 is a circuit that performs impedance matching between the output of the distortion compensation circuit 160d and the amplifier circuit 140d. The matching circuit 240 may have a function of attenuating the fundamental wave and a function of performing impedance matching (impedance conversion) in the frequency range of the second harmonic wave. The provision of the matching circuit 240 for the power amplifier circuit 100d may be omitted.

The power amplifier circuit 100d can generate a signal for suppressing third-order intermodulation distortion without using a filter circuit, thereby making it possible to diminish the influence of intermodulation distortion as well as to reduce the circuit scale.

[symbol]

Power Amplifier Circuit 100e according to Fifth Embodiment

[symbol]

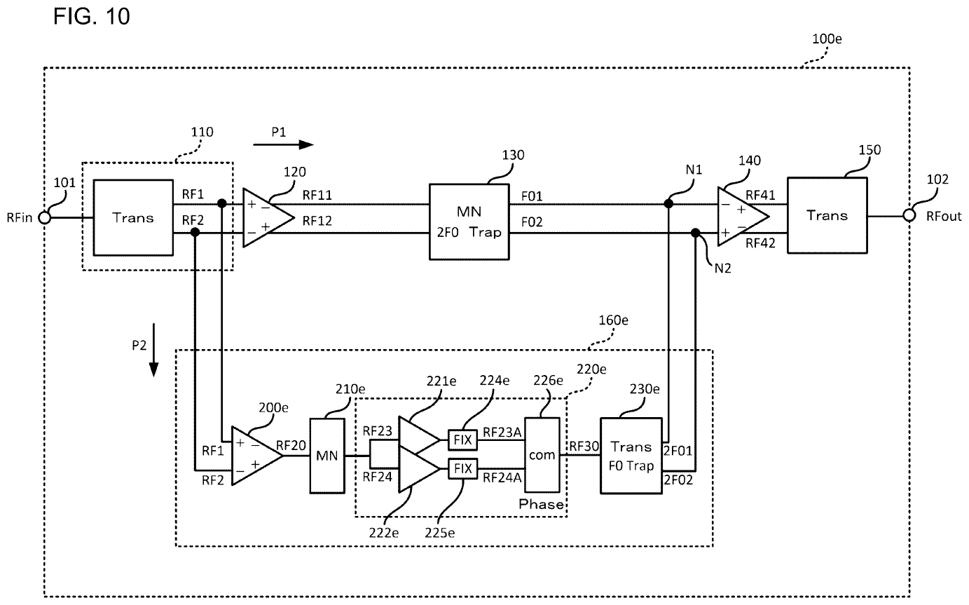

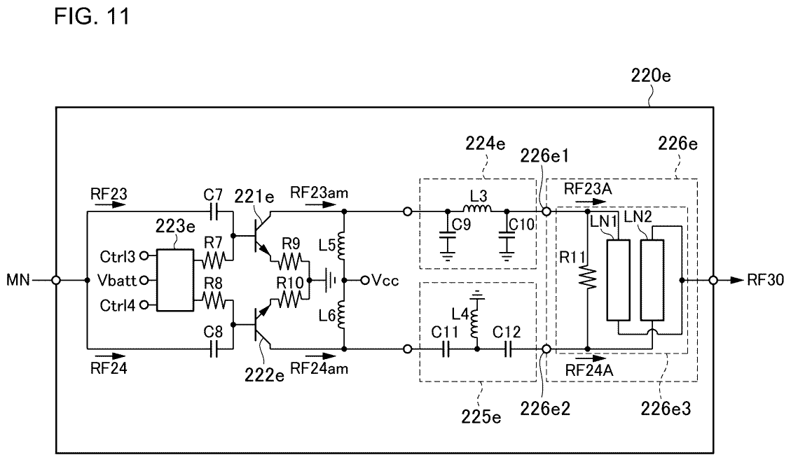

A power amplifier circuit 100e according to a fifth embodiment will be described below with reference to FIGS. 10 and 11. FIG. 10 illustrates an example of the configuration of the power amplifier circuit 100e according to the fifth embodiment. FIG. 11 illustrates an example of the configuration of a phase adjusting circuit 220e of the power amplifier circuit 100e of the fifth embodiment. Hereinafter, reference will be given only to the points different from those of the power amplifier circuit 100a of the first embodiment while an explanation of the same points as the power amplifier circuit 100a is being omitted. Similar advantages obtained by the similar configurations of the power amplifier circuit 100a of the first embodiment will not be discussed.

Unlike the power amplifier circuit 100a in FIG. 1, the power amplifier circuit 100e does not include the distortion compensation circuit 160 provided with the divider 210. Instead, the power amplifier circuit 100e includes a distortion compensation circuit 160e provided with a phase adjusting circuit 220e that adjusts the phases of two signals and then combines the signals while securing the isolation therebetween. By the provision of the phase adjusting circuit 220e, the power amplifier circuit 100e can reduce the occurrence of impedance mismatching of two transistors included in the phase adjusting circuit 220e, thereby making it possible to stabilize the operation.

As illustrated in FIG. 10, the distortion compensation circuit 160e includes a second-harmonic-wave generating circuit 200e, a matching circuit 210e, the phase adjusting circuit 220e, and a divider 230e. The second-harmonic-wave generating circuit 200e and the divider 230e are similar to the second-harmonic-wave generating circuit 200 and the divider 230 of the power amplifier circuit 100a, and an explanation thereof will thus be omitted.

The matching circuit 210e is a circuit that performs impedance matching between the second-harmonic-wave generating circuit 200e and the phase adjusting circuit 220e. A signal outputted from the matching circuit 210e is divided into a signal RF23 (third combined signal) and a signal RF24 (fourth combined signal) at a node subsequent to the matching circuit 210e.

The phase adjusting circuit 220e is a circuit that adjusts the phases of the signals RF23 and RF24 and combines the adjusted signals and outputs a signal RF30 (adjusted signal). The detailed configuration of the phase adjusting circuit 220e will be described below with reference to FIG. 11.

As illustrated in FIG. 11, the phase adjusting circuit 220e includes transistors 221e and 222e, a bias circuit 223e, first and second phase shifters 224e and 225e, and a signal combiner 226e. The bias circuit 223e is similar to the bias circuit 223 of the power amplifier circuit 100a, and an explanation thereof will thus be omitted.

In the transistor 221e, the signal RF23 is inputted into the base, the emitter is electrically connected to a reference potential, and the collector is electrically connected to the first phase shifter 224e. A power supply Vcc is connected to the collector of the transistor 221e via an inductor L5.

In the transistor 222e, the signal RF24 is inputted into the base, the emitter is electrically connected to a reference potential, and the collector is electrically connected to the second phase shifter 225e. The power supply Vcc is connected to the collector of the transistor 222e via an inductor L6.

The first phase shifter 224e shifts the phase of a signal RF23am (third amplified signal), which is obtained by amplifying the signal F23 outputted from the collector of the transistor 221e, to a first phase and outputs a signal RF23A having the first phase. The first phase shifter 224e adjusts the phase by using an inductor and capacitors, for example. For instance, the first phase shifter 224e includes capacitors C9 and C10 and an inductor L3. One end of the capacitor C9 is electrically connected to a ground. One end of the capacitor C10 is electrically connected to a ground. One end of the inductor L3 is electrically connected to the other end of the capacitor C9, and the other end of the inductor L3 is electrically connected to the other end of the capacitor C10. For example, the signal RF23am is inputted into one end of the inductor L3 and the signal RF23A having the first phase is outputted from the other end of the inductor L3.

The second phase shifter 225e shifts the phase of a signal RF24am (fourth amplified signal), which is obtained by amplifying the signal F24 outputted from the collector of the transistor 222e, to a second phase and outputs a signal RF24A having the second phase. The second phase shifter 225e adjusts the phase by using an inductor and capacitors, for example. For instance, the second phase shifter 225e includes an inductor L4 and capacitors C11 and C12. One end of the inductor L4 is electrically connected to a ground. The signal RF24am is inputted into one end of the capacitor C11. One end of the capacitor C12 is electrically connected to other end of the capacitor C11, and the signal RF24A is outputted from the other end of the capacitor C12. The other end of the inductor L4 is electrically connected to a node that connects the other end of the capacitor C11 and one end of the capacitor C12.

The first phase is neither in phase with nor in opposite phase of the second phase. That is, the first and second phase shifters 224e and 225e are designed so that the first phase becomes neither in phase with nor in opposite phase of the second phase. The first phase is desirably out of phase with the second phase by substantially 90 degrees. The first and second phase shifters 224e and 225e are constituted by inductors and capacitors in this manner, and then, the power amplifier circuit 100e can increase the phase adjustable range.

The signal combiner 226e combines the signals RF23A and RF24A and outputs the signal RF30. The signal combiner 226e includes first and second input units 226e1 and 226e2 and a combining unit 226e3, for example.

The first input unit 226e1 is a terminal that receives the signal RF23A. The second input unit 226e2 is a terminal that receives the signal RF24A. A resistor R11 is provided to electrically connect the first and second input units 226e1 and 226e2 to each other.

The combining unit 226e3 combines the signal RF23A having the first phase and the signal RF24A having the second phase and outputs the signal RF30. The combining unit 226e3 includes, for example, a first line LN1 and a second line LN2 that are electromagnetically coupled with each other. The signal RF23A is inputted into one end of the first line LN1. The signal RF24A is inputted into one end of the second line LN2. The other end of the second line LN2 is electrically connected to the other end of the first line LN1. In the combining unit 226e3, the signal RF30 is outputted from a node between the other end of the first line LN1 and the other end of the second line LN2. With this configuration, the power amplifier circuit 100e can implement isolation in the AC circuit, and each of the transistors 222e and 223e can ignore impedance of the other one of the transistors 222e and 223e.

The mechanism in which the power amplifier circuit 100e can implement isolation in the AC circuit will be explained below. In the power amplifier circuit 100e, the first input unit 226e1 and the second input unit 226e2 can be isolated from each other in the AC circuit. This will be explained more specifically. In the power amplifier circuit 100e, the first input unit 226e1 and the second input unit 226e2 are electrically symmetrical to each other. A signal (excitation signal) inputted into the first input unit 226e1 of the combining unit 226e3 is divided into components traveling toward the first line LN1 and those toward the resistor R11. Then, since the first line LN1 and the second line LN2 are electromagnetically coupled with each other, a signal in the opposite direction of the signal flowing through the first line LN1 is induced in the second line LN2. In the second input unit 226e2, the signal input via the resistor R11 and the signal induced in the second line LN2 are combined with each other. That is, in the power amplifier circuit 100e, this combined signal and the signal inputted into the second input unit 226e2 (signal input via the second phase shifter 225e) act to cancel each other out. In the power amplifier circuit 100e, by suitably designing the resistor R11 and the first and second lines LN1 and LN2, the magnitude of the combined signal and that of the signal inputted into the second input unit 226e2 can be made equal to each other. This can prevent the signal from flowing out from the second input unit 226e2 toward the second phase shifter 225e, thereby securing isolation between the first input unit 226e1 and the second input unit 226e2. As stated above, the first input unit 226e1 and the second input unit 226e2 are electrically symmetrical to each other. Hence, when a signal (excitation signal) is inputted into the second input unit 226e2, the above-described explanation of the mechanism also holds true by replacing the first line LN1 by the second line LN2 and vice versa and by replacing the first input unit 226e1 by the second input unit 226e2 and vice versa. That is, the signal can be prevented from flowing out from the first input unit 226e1 toward the first phase shifter 224e.

As described above, in the signal combiner 226e, the first input unit 226e1 and the second input unit 226e2 can be isolated from each other, and also, two signals out of phase with each other can be combined and output as the signal RF30.

### First Modified Example

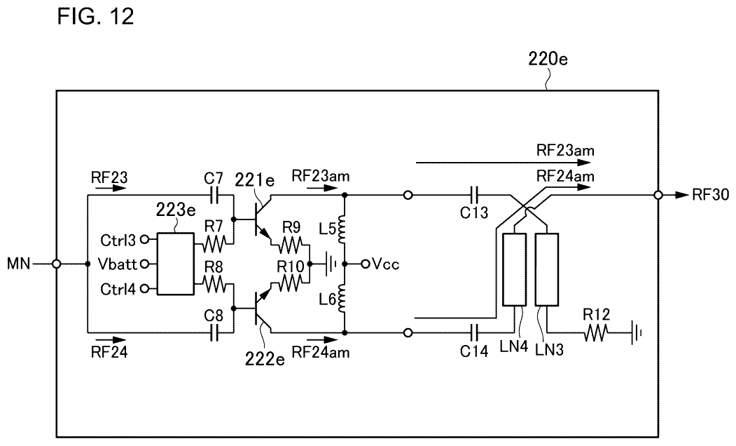

A first modified example of the power amplifier circuit 100e will be described below with reference to FIG. 12. FIG. 12 illustrates the configuration of the phase adjusting circuit 220e in the first modified example of the power amplifier circuit 100e of the fifth embodiment. Hereinafter, reference will be given only to the points different from those of the above-described power amplifier circuit 100e while an explanation of the same points as the power amplifier circuit 100e is being omitted. Similar advantages obtained by the similar configurations of the power amplifier circuit 100e will not be discussed.

As shown in FIG. 12, in the power amplifier circuit 100e, the provision of the first and second phase shifters 224e and 225e for the phase adjusting circuit 220e may be omitted. In this case, the signal combiner 226e is configured to be able to shift the phase of the signal RF24amto a phase that is neither in phase with nor in opposite phase of the signal RF23am, for example.

This will be explained more specifically. As shown in FIG. 12, the signal combiner 226e includes a third line LN3 and a fourth line LN4 that are electromagnetically coupled with each other. The signal RF23am is inputted into one end of the third line LN3 via a capacitor C13, and the other end of the third line LN3 is electrically connected to a reference potential via a resistor R12. The signal RF24am is inputted into one end of the fourth line LN4 (λ/4 line, for example) via a capacitor C14. The fourth line LN4 delays the phase of the signal RF24am by substantially 90 degrees, for example, combines the signal 23am and the signal RF24am having the shifted phase with each other, and outputs the combined signal as the signal RF30 from the other end.

With this configuration, the power amplifier circuit 100e according to the first modified example, which is configured in a simple structure, can secure isolation between the first input unit 226e1 and the second input unit 226e2 and also combine two signals out of phase with each other and outputs the signal RF30.

### Second Modified Example

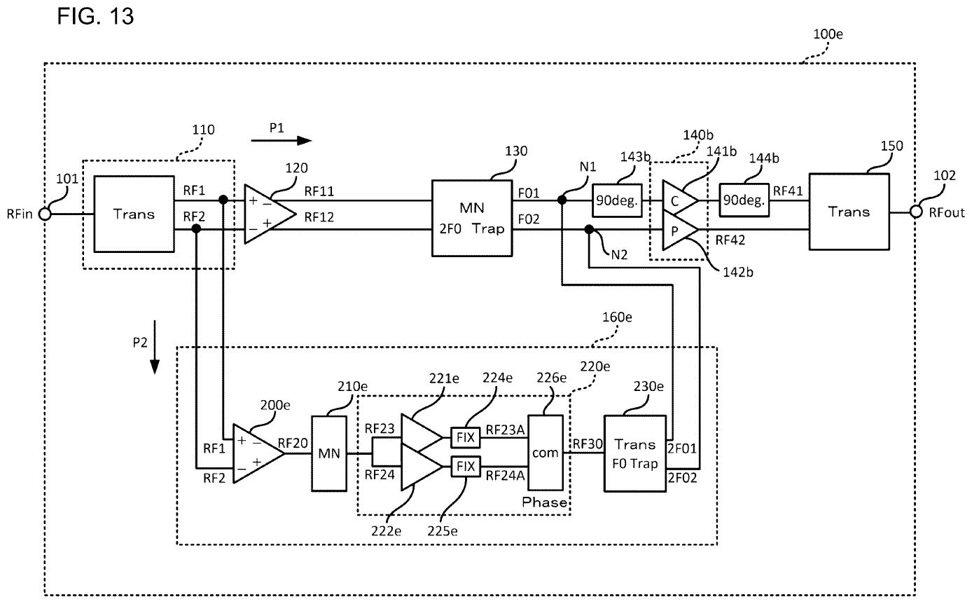

A second modified example of the power amplifier circuit 100e will be described below with reference to FIG. 13. FIG. 13 illustrates the configuration of the second modified example of the power amplifier circuit 100e of the fifth embodiment. In the power amplifier circuit 100e of the second modified example, the distortion compensation circuit 160e of the power amplifier circuit 100e is used instead of the distortion compensation circuit 160 of the power amplifier circuit 100b of the second embodiment. That is, as shown in FIG. 13, in the power amplifier circuit 100e of the second modified example, the divider 230e divides the signal RF30 outputted from the phase adjusting circuit 220 into a signal 2F₀₁ and a signal 2F₀₂ that are out of phase with each other by substantially 180 degrees. The divider 230e then inputs the signal 2F₀₁ into the carrier amplifier 141b via the first phase shifter 143b and the signal 2F₀₂ into the peak amplifier 142b.

In the power amplifier circuit 100e according to the second modified example, the provision of the Doherty amplifier circuit 140b can improve back-off. Additionally, in the power amplifier circuit 100e, while the occurrence of impedance mismatching of two transistors 221e and 222e included in the phase adjusting circuit 220e is being reduced, the linearity of gain can be enhanced by outputting a signal for reducing third-order intermodulation distortion from the distortion compensation circuit 160e to the Doherty amplifier circuit 140b.

### Third Modified Example

A third modified example of the power amplifier circuit 100e will be described below with reference to FIG.

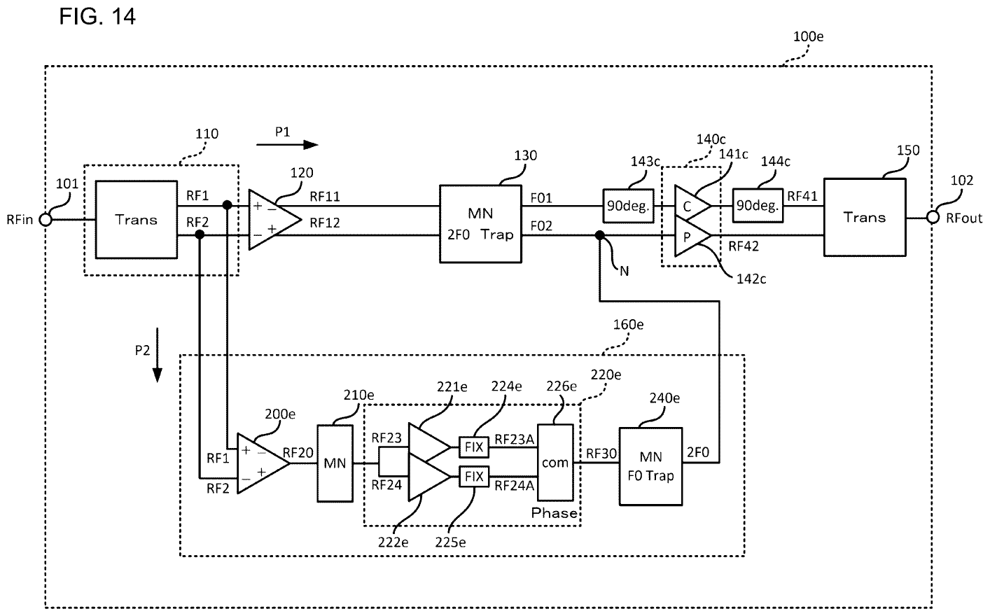

14. FIG. 14 illustrates the configuration of the third modified example of the power amplifier circuit 100e of the fifth embodiment. In the power amplifier circuit 100e of the third modified example, the distortion compensation circuit 160e of the power amplifier circuit 100e is used instead of the distortion compensation circuit 160c of the power amplifier circuit 100c of the third embodiment. The distortion compensation circuit 160e in the third modified example does not include the divider 230e. That is, as shown in FIG. 14, in the power amplifier circuit 100e of the third modified example, the phase adjusting circuit 220e combines the signals RF23A and RF24A whose phases and amplitudes are adjusted and outputs the signal RF30. The signal 2F₀ obtained by attenuating the fundamental wave of the signal RF30 is then outputted to the node N.

In the power amplifier circuit 100e according to the third modified example, the provision of the Doherty amplifier circuit 140c can improve back-off. Additionally, in the power amplifier circuit 100e, while the occurrence of impedance mismatching of two transistors 221e and 222e is being reduced, the linearity can be enhanced by outputting the signal 2F₀ used for reducing third-order intermodulation distortion from the distortion compensation circuit 160c to the peak amplifier 142c, whose linearity is poorer, included in the Doherty amplifier circuit 140c. The divider 230e can be omitted from the power amplifier circuit 100e, thereby making it possible to reduce the circuit scale.

### Fourth Modified Example

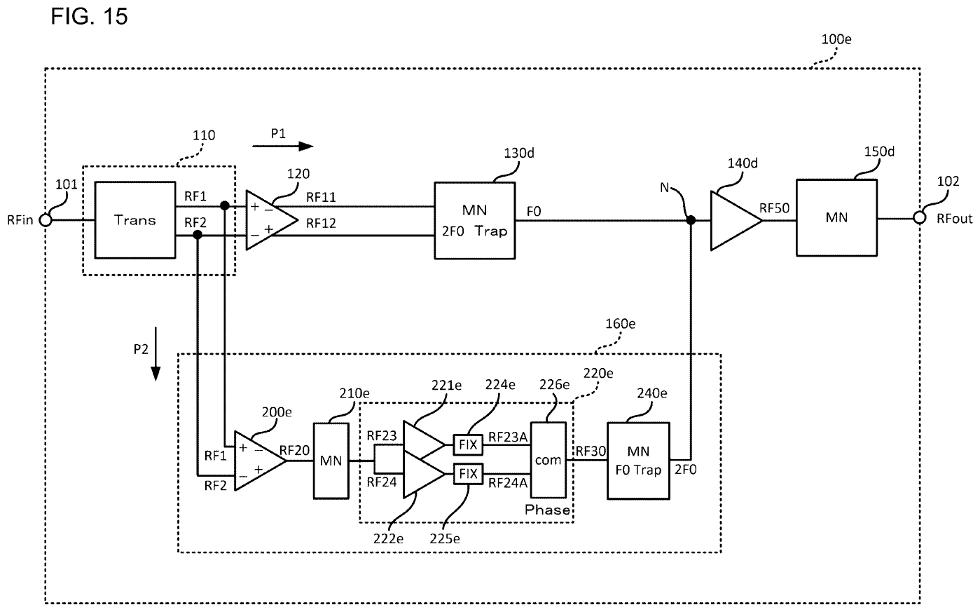

A fourth modified example of the power amplifier circuit 100e will be described below with reference to FIG. 15. FIG. 15 illustrates the configuration of the fourth modified example of the power amplifier circuit 100e of the fifth embodiment. In the power amplifier circuit 100e of the fifth modified example, the distortion compensation circuit 160e of the power amplifier circuit 100e is used instead of the distortion compensation circuit 160d of the power amplifier circuit 100d of the fourth embodiment. The distortion compensation circuit 160e in the fourth modified example includes a matching circuit 240e instead of the divider 230e. The matching circuit 240e is the same as the matching circuit 240 shown in FIG. 9 and an explanation thereof will thus be omitted. That is, as shown in FIG. 15, in the power amplifier circuit 100e of the fourth modified example, while impedance matching is being performed between the output of the distortion compensation circuit 160d and the amplifier circuit 140d, the phase adjusting circuit 220e combines the signals RF23A and RF24A whose phases and amplitudes are adjusted and outputs the signal RF30. The signal 2F₀ obtained by attenuating the fundamental wave of the signal RF30 is then outputted to the node N.

The power amplifier circuit 100e of the fourth modified example can generate a signal for suppressing third-order intermodulation distortion without using a filter circuit while reducing the occurrence of impedance mismatching of two transistors 221e and 222e. This makes it possible to diminish the influence of intermodulation distortion as well as to reduce the circuit scale. [symbol] CONCLUSION

[symbol]

<1> A power amplifier circuit 100a according to an embodiment of the present disclosure includes a divider circuit 110, a second-harmonic-wave generating circuit 200, and an amplifier circuit 140 (first amplifier circuit). The divider circuit 110 divides an input signal RFin into a signal RF1 (first signal) and a signal RF2 (second signal) and outputs the signal RF1 (first signal) to a main path P1 and the signal RF2 (second signal) to a sub-path P2. The signal RF1 (first signal) and the signal RF2 (second signal) are out of phase with each other by substantially 180 degrees. The second-harmonic-wave generating circuit 200 is disposed on the sub-path P2 and combines the signal RF1 (first signal) and the signal RF2 (second signal) with each other so that the fundamental wave of the signal RF1 (first signal) and that of the signal RF2 (second signal) cancel each other out and so that a signal having a frequency band of a second harmonic wave of the signal RF1 (first signal) and a signal having a frequency band of a second harmonic wave of the signal RF2 (second signal) are added to each other, thereby generating a signal RF20 (second-harmonic-wave combined signal). The amplifier circuit 140 (first amplifier circuit) amplifies a signal, which is obtained by combining signals F₀₁ and F₀₂ (fundamental signals) based on the signal RF1 (first signal) and the signal RF2 (second signal) received via the main path P1 and signals 2F₀₁ and 2F₀₂ (adjusted signal) based on the signal RF20 (second-harmonic-wave combined signal) received via the sub-path P2 with each other, and outputs signals RF41 and RF42 (amplified signal). With this configuration, the power amplifier circuit 100a is able to diminish the influence of intermodulation distortion as well as to reduce the circuit scale.

<2> A power amplifier circuit 100a according to an embodiment of the present disclosure further includes a phase adjusting circuit 220 and a divider 230 (adjusting circuit). The adjusting circuit 220 and the divider 230 (adjusting circuit) are disposed on the sub-path P2 and adjust the phase of the signal RF20 (second-harmonic-wave combined signal) and output the signals 2F₀₁ and 2F₀₂ (adjusted signal). With this configuration, the power amplifier circuit 100a is able to suitably diminish the influence of intermodulation distortion as well as to reduce the circuit scale.

<3> A power amplifier circuit 100a according to an embodiment of the present disclosure is the power amplifier circuit according to <1>or <2> having the following configuration. The second-harmonic-wave generating circuit 200 includes a transistor 201 (first transistor) and a transistor 201 (second transistor). In the transistor 201 (first transistor), the signal RF1 (first signal) is inputted into the base or the gate, and the emitter or the source is electrically connected to a reference potential. In the transistor 202 (second transistor), the signal RF2 (second signal) is inputted into the base or the gate, the emitter or the source is electrically connected to a reference potential, and the collector or the drain is electrically connected to the collector or the drain of the transistor 201 (first transistor). With this configuration, the power amplifier circuit 100a is able to attenuate the fundamental wave and output the second harmonic wave without using a filter circuit, thereby making it possible to reduce the circuit scale.

<4> A power amplifier circuit 100a according to an embodiment of the present disclosure is the power amplifier circuit according to <2> having the following configuration. The phase adjusting circuit 220 and the divider 230 (adjusting circuit) adjust the phase of the signal RF20 (second-harmonic-wave combined signal) so that third-order intermodulation distortion occurring in the amplifier circuit 140 (first amplifier circuit) becomes out of phase with a differential signal between the second harmonic wave and the fundamental wave of the signals RF41 and RF42 (amplified signal) by substantially 180 degrees in output of the amplifier circuit 140 (first amplifier circuit), and output the signals 2F₀₁ and 2F₀₂ (adjusted signal). With this configuration, even if the operating condition, such as the frequency, temperature, or power supply voltage, is changed, the power amplifier circuit 100a is able to output the signals 2F₀₁ and 2F₀₂ (adjusted signal) suitable for distortion compensation in accordance with the changed operating condition.

<5> A power amplifier circuit 100a according to an embodiment of the present disclosure is the power amplifier circuit according to <4> having the following configuration. The power amplifier circuit 100a further includes a divider 210 (first divider). The divider 210 (first divider) is disposed on the sub-path P2 and divides the signal RF20 (second-harmonic-wave combined signal) into a signal RF21 (first combined signal) and a signal RF22 (second combined signal) that are out of phase with each other by substantially 90 degrees. The phase adjusting circuit 220 (adjusting circuit) includes a transistor 221 (third transistor) and a transistor 222 (fourth transistor). In the transistor 221 (third transistor), the signal RF21 (first combined signal) is inputted into the base or the gate, and the emitter or the source is electrically connected to a reference potential. In the transistor 222 (fourth transistor), the signal RF22 (second combined signal) is inputted into the base or the gate, the emitter or the source is electrically connected to a reference potential, and the collector or the drain is electrically connected to the collector or the drain of the transistor 221 (third transistor). A bias is supplied to the base or the gate of the transistor 221 (third transistor) to adjust the gain of the transistor 221 (third transistor). A bias is supplied to the base or the gate of the transistor 222 (fourth transistor) to adjust the gain of the transistor 222 (fourth transistor). With this configuration, even if the operating condition, such as the frequency, temperature, or power supply voltage, is changed, the power amplifier circuit 100a with a simple structure is able to output the signals 2F₀₁ and 2F₀₂ (adjusted signal) suitable for distortion compensation in accordance with the changed operating condition.

<6> A power amplifier circuit 100a according to an embodiment of the present disclosure is the power amplifier circuit according to one of <1> to <5> having the following configuration. The power amplifier circuit 100a further includes a second-harmonic-wave attenuation circuit 130 (output circuit). The second-harmonic-wave attenuation circuit 130 (output circuit) is disposed on the main path P1 and outputs the signals F₀₁ and F₀₂ (fundamental signal) by attenuating the signal having the frequency band of the second harmonic wave of the signal RF1 (first signal) and the signal having the frequency band of the second harmonic wave of the signal RF2 (second signal). With this configuration, in the power amplifier circuit 100a, the second harmonic wave contained in the signal passing through the main path P1 can be prevented from being supplied to the amplifier circuit 140. This can avoid the deterioration of the distortion compensation effect, which may be caused by the second harmonic wave passing through the main path P1 canceling out the signals 2F₀₁ and 2F₀₂ (adjusted signal) that have not been inputted into the amplifier circuit 140.

<7> A power amplifier circuit 100a according to an embodiment of the present disclosure is the power amplifier circuit according to one of <1> to <6> having the following configuration. The power amplifier circuit 100a further includes a second-harmonic-wave attenuation circuit 130 (output circuit) and a divider 230 (second divider). The second-harmonic-wave attenuation circuit 130 (output circuit) is disposed on the main path P1 and outputs a signal F₀₁ (first fundamental signal) corresponding to the signal RF1 (first signal) and a signal F₀₂ (second fundamental signal) corresponding to the signal RF2 (second signal). The signal F₀₁ (first fundamental signal) and the signal F₀₂ (second fundamental signal) are out of phase with each other by substantially 180 degrees. The divider 230 (second divider) is disposed on the sub-path P2 and divides the signal RF30 (adjusted signal) into a signal 2F₀₁ (first adjusted signal) and a signal 2F₀₂ (second adjusted signal). The signal 2F₀₁ (first adjusted signal) and the signal 2F₀₂ (second adjusted signal) are out of phase with each other by about 180 degrees. The amplifier circuit 140 (first amplifier circuit) includes a transistor 141 (first amplifier) and a transistor 142 (second amplifier). The transistor 141 (first amplifier) amplifies a signal obtained by combining the signal F₀₁ (first fundamental signal) and the signal 2F₀₁ (first adjusted signal) with each other and outputs a signal RF41 (first amplified signal). The transistor 142 (second amplifier) amplifies a signal obtained by combining the signal F₀₂ (second fundamental signal) and the signal 2F₀₂ (second adjusted signal) with each other and outputs a signal RF42 (second amplified signal). In the power amplifier circuit 100a, by the use of a differential power amplifier circuit for the power stage, the output impedance is increased, which can lower the impedance of a load, thereby achieving high output.

<8> A power amplifier circuit 100b according to an embodiment of the present disclosure is the power amplifier circuit according to one of <1> to <6> having the following configuration. The power amplifier circuit 100b further includes a second-harmonic-wave attenuation circuit 130 (output circuit) and a divider 230 (second divider). The second-harmonic-wave attenuation circuit 130 (output circuit) outputs a signal F₀₁ (first fundamental signal) corresponding to the signal RF1 (first signal) and a signal F₀₂ (second fundamental signal) corresponding to the signal RF2 (second signal). The phase of the signal F₀₂ (second fundamental signal) is delayed with respect to the phase of the signal F₀₁ (first fundamental signal) by substantially 180 degrees. The divider 230 (second divider) is disposed on the sub-path P2 and divides the signal RF30 (adjusted signal) into a signal 2F₀₁ (first adjusted signal) and a signal 2F₀₂ (second adjusted signal). The signal 2F₀₁ (first adjusted signal) and the signal 2F₀₂ (second adjusted signal) are out of phase with each other by about 180 degrees. An amplifier circuit 140b (first amplifier circuit) includes a Doherty amplifier circuit 140b. The Doherty amplifier circuit 140b includes a carrier amplifier 141b (carrier amplifier) and a peak amplifier 142b (peak amplifier). The carrier amplifier 141b (carrier amplifier) amplifies a signal obtained by combining the signal F₀₁ (first fundamental signal) and the signal 2F₀₁ (first adjusted signal) with each other and outputs a signal RF41 (first amplified signal). The combined signal of the signal F₀₁ (first fundamental signal) and the signal 2F₀₁ (first adjusted signal) is inputted into the carrier amplifier 141b (carrier amplifier) via a first phase shifter 143b that delays the phase by substantially 90 degrees. The signal RF41 (first amplified signal) is outputted from the carrier amplifier 141b (carrier amplifier) via a second phase shifter 144b that delays the phase by substantially 90 degrees. The peak amplifier 142b (peak amplifier) amplifies a signal obtained by combining the signal F₀₂ (second fundamental signal) and the signal 2F₀₂ (second adjusted signal) with each other and outputs a signal RF42 (second amplified signal). With this configuration, in the power amplifier circuit 100b, the provision of the Doherty amplifier circuit 140b can improve back-off. Additionally, in the power amplifier circuit 100b, by outputting a signal for reducing third-order intermodulation distortion from the distortion compensation circuit 160 to the Doherty amplifier circuit 140b, the linearity of gain can be enhanced.

<9> A power amplifier circuit 100c according to an embodiment of the present disclosure is the power amplifier circuit according to one of <1> to <6> having the following configuration. The power amplifier circuit 100c further includes a second-harmonic-wave attenuation circuit 130 (output circuit). The second-harmonic-wave attenuation circuit 130 (output circuit) outputs a signal F₀₁ (first fundamental signal) corresponding to the signal RF1 (first signal) and a signal F₀₂ (second fundamental signal) corresponding to the signal RF2 (second signal). The signal F₀₁ (first fundamental signal) and the signal F₀₂ (second fundamental signal) are out of phase with each other by substantially 180 degrees. An amplifier circuit 140c (first amplifier circuit) includes a Doherty amplifier circuit 140c. The Doherty amplifier circuit 140c includes a carrier amplifier 141c (carrier amplifier) and a peak amplifier 142c (peak amplifier). The carrier amplifier 141c (carrier amplifier) amplifies the signal F₀₁ (first fundamental signal) and outputs a signal RF41 (first amplified signal). The signal F₀₁ (first fundamental signal) is inputted into the carrier amplifier 141c (carrier amplifier) via a first phase shifter 143c that delays the phase by substantially 90 degrees. The signal RF41 (first amplified signal) is outputted from the carrier amplifier 141c (carrier amplifier) via a second phase shifter 144c that delays the phase by substantially 90 degrees. The peak amplifier 142c (peak amplifier) amplifies a signal obtained by combining the signal F₀₂ (second fundamental signal) and the signal 2F₀ (adjusted signal) with each other and outputs a signal RF42 (second amplified signal). With this configuration, in the power amplifier circuit 100c, the provision of the Doherty amplifier circuit 140c can improve back-off. Additionally, in the power amplifier circuit 100c, by outputting the signal 2F₀ used for reducing third-order intermodulation distortion from the distortion compensation circuit 160c to the peak amplifier 142c, whose gain linearity is poorer, included in the Doherty amplifier circuit 140c, the linearity can be enhanced. The divider 230 provided in the power amplifier circuit 100b can be omitted from the power amplifier circuit 100c, thereby making it possible to reduce the circuit scale.

<10> A power amplifier circuit 100d according to an embodiment of the present disclosure is the power amplifier circuit according to one of <1> to <4> having the following configuration. The power amplifier circuit 100d further includes a second-harmonic-wave attenuation circuit 130d (output circuit). The second-harmonic-wave attenuation circuit 130d (output circuit) receives the signal RF1 (first signal) and the signal RF2 (second signal) and outputs the single signal F₀ (fundamental signal). An amplifier circuit 140d (first amplifier circuit) amplifies a signal obtained by combining the single signal F₀ (fundamental signal) and the signal 2F₀ (adjusted signal) and outputs the signal RF50 (amplified signal). With this configuration, the power amplifier circuit 100d can generate a signal for suppressing third-order intermodulation distortion without using a filter circuit, thereby making it possible to diminish the influence of intermodulation distortion as well as to reduce the circuit scale.

<11> A power amplifier circuit 100a according to an embodiment of the present disclosure is the power amplifier circuit according to one of <1> to <10> having the following configuration. The power amplifier circuit 100a further includes an amplifier circuit 120 (second amplifier circuit) and a second-harmonic-wave attenuation circuit 130 (output circuit). The amplifier circuit 120 (second amplifier circuit) is disposed on the main path P1 and amplifies the signal RF1 (first signal) and the signal RF2 (second signal). The second-harmonic-wave attenuation circuit 130 (output circuit) attenuates the signal having the frequency band of the second harmonic wave of the signal RF1 (first signal) amplified in the amplifier circuit 120 (second amplifier circuit) and the signal having the frequency band of the second harmonic wave of the signal RF2 (second signal) amplified in the second amplifier circuit and outputs the signals F₀₁ and F₀₂ (fundamental signal). With this configuration, the power amplifier circuit 100a is able to diminish the influence of intermodulation distortion as well as to reduce the circuit scale.

<12> A power amplifier circuit 100e according to an embodiment of the present disclosure is the power amplifier circuit according to <4> having the following configuration. A phase adjusting circuit 220e (adjusting circuit) is a circuit that receives a signal RF23 (third combined signal) and a signal RF24 (fourth combined signal) which are obtained by dividing the signal RF20 (second-harmonic-wave combined signal). The phase adjusting circuit 220e (adjusting circuit) includes third and fourth transistors and a signal combiner 226e. In the third transistor, the signal RF23 (third combined signal) is inputted into the base or the gate, the emitter or the source is electrically connected to a reference potential, and the signal RF23 (third combined signal) is amplified in the third transistor and a signal RF23am (third amplified signal) is outputted from the collector or the drain of the third transistor. In the fourth transistor, the signal RF24 (fourth combined signal) is inputted into the base or the gate of the fourth transistor, the emitter or the source is electrically connected to a reference potential, and the signal RF24 (fourth combined signal) is amplified in the fourth transistor and a signal RF24am (fourth amplified signal) is outputted from the collector or the drain of the fourth transistor. The signal combiner 226e is able to isolate a first input unit 226e1 and a second input unit 226e2 from each other. The signal RF23am (third amplified signal) is inputted into the first input unit 226e1. The signal RF24am (fourth amplified signal) is inputted into the second input unit 226e2. The signal combiner 226e combines the signal RF23am (third amplified signal) and the signal RF24am (fourth amplified signal) with each other and outputs the signals 2F₀₁ and 2F₀₂ (adjusted signal). A bias is supplied to the base or the gate of the transistor 221e (third transistor) to adjust the gain of the transistor 221e (third transistor). A bias is supplied to the base or the gate of the transistor 222e (fourth transistor) to adjust the gain of the transistor 222e (fourth transistor). With this configuration, the power amplifier circuit 100e can reduce the occurrence of impedance mismatching of two transistors included in the phase adjusting circuit 220e, thereby making it possible to stabilize the operation.

<13> A power amplifier circuit 100e according to an embodiment of the present disclosure is the power amplifier circuit according to <12> having the following configuration. The phase adjusting circuit 220e (adjusting circuit) includes a first phase shifter 224e and a second phase shifter 225e. The first phase shifter 224e shifts the phase of the signal RF23am (third amplified signal) outputted from the collector or the drain of the transistor 221e (third transistor) to a first phase and outputs a signal RF23A having the first phase (third amplified signal having the first phase) to the first input unit 226e1 of the signal combiner 226e. The second phase shifter 225e shifts the phase of the signal RF24am (fourth amplified signal) outputted from the collector or the drain of the transistor 222e (fourth transistor) to a second phase and outputs a signal RF24A having the second phase (fourth amplified signal having the second phase) to the second input unit 226e2 of the signal combiner 226e. The second phase is neither in phase with nor in opposite phase of the first phase. With this configuration, even if the operating condition, such as the frequency, temperature, or power supply voltage, is changed, the power amplifier circuit 100e with a simple structure is able to output the signals 2F₀₁ and 2F₀₂ (adjusted signal) suitable for distortion compensation in accordance with the changed operating condition.

<14> A power amplifier circuit 100e according to an embodiment of the present disclosure is the power amplifier circuit according to <12> having the following configuration. The signal combiner 226e includes a first line LN1 and a second line LN2 that are electromagnetically coupled with each other. The signal RF23am (third amplified signal) or the signal RF23A is inputted into one end of the first line LN1. The signal RF24am (fourth amplified signal) or the signal RF24A is inputted into one end of the second line LN2. The other end of the first line LN1 and the other end of the second line LN2 are electrically connected to each other. The signals 2F₀₁ and 2F₀₂ (adjusted signal) are outputted from a node between the other end of the first line LN1 and the other end of the second line LN2. With this configuration, the power amplifier circuit 100e with a simple structure is able to isolate the first input unit 226e1 and the second input unit 226e2 from each other and to combine two signals out of phase with each other and output the signal RF30.

<15> A power amplifier circuit 100e according to an embodiment of the present disclosure is the power amplifier circuit according to <12> having the following configuration. The signal combiner 226e includes a third line LN3 and a fourth line LN4. The signal RF23am (third amplified signal) is inputted into one end of the third line LN3. The other end of the third line LN3 is electrically connected to a reference potential. The fourth line LN4 is electromagnetically coupled with the third line LN3. The fourth line LN4 delays the phase of the signal RF24am (fourth amplified signal) inputted from one end of the fourth line LN4 by substantially 90 degrees. The signal combiner 226e combines the signal RF23am (third amplified signal) and the signal RF24am (fourth amplified signal) having the delayed phase with each other and outputs the signals 2F₀₁ and 2F₀₂ (adjusted signal) from the other end of the fourth line LN4. With this configuration, the power amplifier circuit 100e with a simpler structure is able to isolate the first input unit 226e1 and the second input unit 226e2 from each other and to combine two signals out of phase with each other and output the signal RF30.

The above-described embodiments are provided for facilitating the understanding of the disclosure, but are not intended to be exhaustive or to limit the disclosure to the precise forms disclosed. Modifications or improvements may be made without departing from the scope and spirit of the disclosure, and equivalents of the disclosure are also encompassed in the disclosure. That is, suitable design changes made to the embodiments by those skilled in the art are also encompassed in the disclosure within the scope and spirit of the disclosure. For example, the elements of the embodiments and the positions, materials, conditions, shapes, and sizes thereof are not limited to those described in the embodiments and may be changed in an appropriate manner. The elements of the embodiments may be combined within a technically possible range, and configurations obtained by combining the elements of the embodiments are also encompassed in the disclosure within the scope and spirit of the disclosure.

100a, 100a, 100c, 100d, 100e power amplifier circuit, 110 divider circuit, 120 amplifier circuit, 130, 130d second-harmonic-wave attenuation circuit, 140, 140b, 140c, 140d amplifier circuit, 150 combiner circuit, 160, 160d, 160e distortion compensation circuit, 200, 200e second-harmonic-wave generating circuit, 210, 210e divider, 220, 220e phase adjusting circuit, 230, 230e divider, P1 main path, P2 sub-path

1. A power amplifier circuit comprising:
a divider circuit configured to divide an input signal into a first signal and a second signal, and to output the first signal to a main path and the second signal to a sub-path, the first signal and the second signal being out of phase with each other by 180 degrees;
a second-harmonic-wave generating circuit that is on the sub-path and that is configured to combine the first signal and the second signal with each other so that a fundamental wave of the first signal and a fundamental wave of the second signal cancel each other out and so that a signal having a frequency band of a second harmonic wave of the first signal and a signal having a frequency band of a second harmonic wave of the second signal are added to each other, thereby generating a second-harmonic-wave combined signal; and
a first amplifier circuit configured to amplify a signal obtained by combining a fundamental signal based on the first and second signals received via the main path and an adjusted signal based on the second-harmonic-wave combined signal received via the sub-path with each other, and to output an amplified signal.

2. The power amplifier circuit according to claim 1, further comprising:
an adjusting circuit that is on the sub-path, and that is configured to adjust a phase of the second-harmonic-wave combined signal and to output the adjusted signal.

3. The power amplifier circuit according to claim 1, wherein the second-harmonic-wave generating circuit comprises:
a first transistor, the first signal being input into a base or a gate of the first transistor, an emitter or a source of the first transistor being electrically connected to a reference potential, and
a second transistor, the second signal being input into a base or a gate of the second transistor, an emitter or a source of the second transistor being electrically connected to a reference potential, and a collector or a drain of the second transistor being electrically connected to a collector or a drain of the first transistor.

4. The power amplifier circuit according to claim 2, wherein the adjusting circuit is configured to adjust the phase of the second-harmonic-wave combined signal so that third-order intermodulation distortion occurring in the first amplifier circuit becomes out of phase with a differential signal between a second harmonic wave and a fundamental wave of the amplified signal by 180 degrees in output of the first amplifier circuit, and outputs the adjusted signal.

5. The power amplifier circuit according to claim 4, further comprising:
a first divider that is on the sub-path and that is configured to divide the second-harmonic-wave combined signal into a first combined signal and a second combined signal, the first combined signal and the second combined signal being out of phase with each other by 90 degrees,
wherein the adjusting circuit comprises:
a third transistor, the first combined signal being input into a base or a gate of the third transistor, and an emitter or a source of the third transistor being electrically connected to a reference potential; and
a fourth transistor, the second combined signal being input into a base or a gate of the fourth transistor, an emitter or a source of the fourth transistor being electrically connected to a reference potential, and a collector or a drain of the fourth transistor being electrically connected to a collector or a drain of the third transistor,
wherein a bias is supplied to the base or the gate of the third transistor to adjust gain of the third transistor, and
wherein a bias is supplied to the base or the gate of the fourth transistor to adjust gain of the fourth transistor.

6. The power amplifier circuit according to claim 1, further comprising:
an output circuit that is on the main path and that is configured to output the fundamental signal by attenuating the signal having the frequency band of the second harmonic wave of the first signal and the signal having the frequency band of the second harmonic wave of the second signal.

7. The power amplifier circuit according to claim 1, further comprising:
an output circuit that is on the main path and that is configured to output, as the fundamental signal, a first fundamental signal corresponding to the first signal and a second fundamental signal corresponding to the second signal, the first fundamental signal and the second fundamental signal being out of phase with each other by 180 degrees; and
a second divider that is on the sub-path and that is configured to divide the adjusted signal into a first adjusted signal and a second adjusted signal, the first adjusted signal and the second adjusted signal being out of phase with each other by 180 degrees,
wherein the first amplifier circuit comprises a first transistor configured to amplify a signal obtained by combining the first fundamental signal and the first adjusted signal with each other and to output a first amplified signal, and a second transistor configured to amplify a signal obtained by combining the second fundamental signal and the second adjusted signal with each other and to output a second amplified signal.

8. The power amplifier circuit according to claim 1, further comprising:
an output circuit configured to output, as the fundamental signal, a first fundamental signal corresponding to the first signal and a second fundamental signal corresponding to the second signal, a phase of the second fundamental signal being delayed with respect to a phase of the first fundamental signal by 180 degrees; and
a second divider that is on the sub-path and that is configured to divide the adjusted signal into a first adjusted signal and a second adjusted signal, the first adjusted signal and the second adjusted signal being out of phase with each other by 180 degrees,
wherein the first amplifier circuit comprises a Doherty amplifier circuit, the Doherty amplifier circuit comprising a carrier amplifier and a peak amplifier,
wherein the carrier amplifier being configured to amplify a signal obtained by combining the first fundamental signal and the first adjusted signal with each other and to output a first amplified signal,
wherein the combined signal of the first fundamental signal and the first adjusted signal are input into the carrier amplifier via a first phase shifter configured to delay a phase by 90 degrees,
wherein the first amplified signal is output from the carrier amplifier via a second phase shifter configured to delay a phase by 90 degrees, and
wherein the peak amplifier is configured to amplify a signal obtained by combining the second fundamental signal and the second adjusted signal with each other and to output a second amplified signal.

9. The power amplifier circuit according to claim 1, further comprising:
an output circuit configured to output, as the fundamental signal, a first fundamental signal corresponding to the first signal and a second fundamental signal corresponding to the second signal, the first fundamental signal and the second fundamental signal being out of phase with each other by 180 degrees,
wherein the first amplifier circuit comprises a Doherty amplifier circuit, the Doherty amplifier circuit comprising a carrier amplifier and a peak amplifier,
wherein the carrier amplifier is configured to amplify the first fundamental signal and to output a first amplified signal,
wherein the first fundamental signal is input into the carrier amplifier via a first phase shifter that delays a phase by 90 degrees,
wherein the first amplified signal is output from the carrier amplifier via a second phase shifter configured to delay a phase by 90 degrees, and
wherein the peak amplifier is configured to amplify a signal obtained by combining the second fundamental signal and the adjusted signal with each other and to output a second amplified signal.

10. The power amplifier circuit according to claim 1, further comprising:
an output circuit that is configured to receive the first signal and the second signal, and to output the fundamental signal, which is a single fundamental signal,
wherein the first amplifier circuit is configured to amplify a signal obtained by combining the single fundamental signal and the adjusted signal, and to output the amplified signal.

11. The power amplifier circuit according to claim 1, further comprising:
a second amplifier circuit that is on the main path and that is configured to amplify the first signal and the second signal; and
an output circuit that is configured to attenuate the signal having the frequency band of the second harmonic wave of the first signal amplified in the second amplifier circuit and the signal having the frequency band of the second harmonic wave of the second signal amplified in the second amplifier circuit, and to output the fundamental signal.

12. The power amplifier circuit according to claim 4,
wherein the adjusting circuit is configured to receive third and fourth combined signals which are obtained by dividing the second-harmonic-wave combined signal,
wherein the adjusting circuit comprises:
a third transistor, the third combined signal being input into a base or a gate of the third transistor, an emitter or a source of the third transistor being electrically connected to a reference potential, the third combined signal being amplified in the third transistor, and a third amplified signal being output from a collector or a drain of the third transistor;
a fourth transistor, the fourth combined signal being input into a base or a gate of the fourth transistor, an emitter or a source of the fourth transistor being electrically connected to a reference potential, the fourth combined signal being amplified in the fourth transistor, and a fourth amplified signal being output from a collector or a drain of the fourth transistor; and
a signal combiner that is configured to isolate a first input unit and a second input unit from each other, to combine the third amplified signal and the fourth amplified signal with each other, and to output the adjusted signal,
wherein the third amplified signal is input into the first input unit and the fourth amplified signal is input into the second input unit,
wherein a bias is supplied to the base or the gate of the third transistor to adjust gain of the third transistor; and
wherein a bias is supplied to the base or the gate of the fourth transistor to adjust gain of the fourth transistor.

13. The power amplifier circuit according to claim 12, wherein the adjusting circuit further comprises:
a first phase shifter configured to shift a phase of the third amplified signal output from the collector or the drain of the third transistor to a first phase and to output the third amplified signal having the first phase to the first input unit of the signal combiner, and
a second phase shifter configured to shift a phase of the fourth amplified signal output from the collector or the drain of the fourth transistor to a second phase, the second phase being neither in phase with nor in opposite phase of the first phase, and to output the fourth amplified signal having the second phase to the second input unit of the signal combiner.

14. The power amplifier circuit according to claim 12,
wherein the signal combiner comprises first and second lines that are electromagnetically coupled with each other, the third amplified signal being input into a first end of the first line, and the fourth amplified signal being input into a first end of the second line,
wherein a second end of the first line and a second end of the second line are electrically connected to each other, and
wherein the adjusted signal is output from a node between the second end of the first line and the second end of the second line.

15. The power amplifier circuit according to claim 12,
wherein the signal combiner comprises:
a third line, the third amplified signal being input into a first end of the third line, a second end of the third line being electrically connected to a reference potential; and
a fourth line that is electromagnetically coupled with the third line and that is configured to delay a phase of the fourth amplified signal input into a first end of the fourth line so that the fourth amplified signal having the delayed phase is neither in phase with nor in opposite phase of the third amplified signal, and
wherein the signal combiner is configured to combine the third amplified signal and the fourth amplified signal having the delayed phase with each other, and to output the adjusted signal from the second end of the fourth line.
